(19) United States
(12) Patent Application Publication
(10) Pub. No.: US 2026/0141952 A1
(43) Pub. Date: May 21, 2026

(54) MEMORY DEVICE

(71) Applicant: SAMSUNG ELECTRONICS CO., LTD., Suwon-si (KR)

(72) Inventors: Yonghyuk CHOI, Suwon-si (KR); Kwnagho CHOI, Suwon-si (KR)

(73) Assignee: SAMSUNG ELECTRONICS CO., LTD., Suwon-si (KR)

(21) Appl. No.: 19/324,280

(22) Filed: Sep. 10, 2025

(30) Foreign Application Priority Data
Nov. 19, 2024 (KR) 10-2024-0164935

(51) Int. Cl. G11C 16/04

(52) U.S. Cl. CPC G11C 16/0483

(57) ABSTRACT

A memory device includes a memory cell array having at least one memory block with multiple cell strings connected to word lines arranged in one direction and to a plurality of ground selection lines. The cell strings include first and second cell strings, and control logic executes program and read operations for the memory cell array. Ground select transistors coupled to the ground selection lines are programmed with different threshold voltages. The number of memory cells available for storing user data in each of the first and second cell strings is determined based on a positional difference, along the one direction, between a ground select transistor programmed with a higher threshold voltage in the first cell string and a ground select transistor programmed with a higher threshold voltage in the second cell string.

### CROSS-REFERENCE TO RELATED APPLICATION

This application claims priority to Korean Patent Application No. 10-2024-0164935, filed with the Korean Intellectual Property Office on Nov. 19, 2024, the entire contents of which are hereby incorporated by reference.

### BACKGROUND

### Field

The present disclosure relates to a memory device.

### Description of Related Art

Semiconductor memory devices are grouped into volatile memory devices such as SRAM (Static RAM), DRAM (Dynamic RAM), and SDRAM (Synchronous DRAM) that lose stored data when power is blocked, and non-volatile memory devices such as ROM (Read Only Memory), PROM (Programmable ROM), EPROM (Electrically Programmable ROM), EEPROM (Electrically Erasable and Programmable ROM), flash memory devices, PRAM (Phase-change RAM), MRAM (Magnetic RAM), RRAM (Resistive RAM), and FRAM (Ferroelectric RAM) that retain stored data even when power is blocked.

A ground selection line (GSL) controls a current path by selectively grounding individual cells in a semiconductor memory device. The GSL may allow a current to flow at a specific cell to minimize interference between cells, and current leakage, thereby improving data access accuracy and power efficiency. The structure of GSL maintains performance and stability of memory devices, which reduces power consumption, thereby extending the life of memory elements and ensuring data stability.

### SUMMARY

The present disclosure aims to provide a memory device for solving the above-described problem.

The problem to be solved is not limited to above, but the other tasks not mentioned above may be explicitly known to those skilled in the art from the description of the present disclosure below.

According to embodiments of the present disclosure, there is provided a memory cell array including at least one memory block including a plurality of cell strings, each of the plurality of cell strings being connected to one or more word lines WL arranged in one direction, and a plurality of ground selection lines GSL, wherein the plurality of cell strings include a first cell string and a second cell string, and a control logic configured to control at least one of a program operation or a read operation for the memory cell array, wherein a part of the plurality of ground select transistors GST respectively connected to the plurality of ground selection lines is programmed with a first threshold voltage, and other parts of the plurality of ground select transistors is programmed with a second threshold voltage different from the first threshold voltage, wherein a number of memory cells in which user data is stored in each of the first cell string and the second cell string varies depending on a difference between a first location in the one direction of a ground select transistor programmed with the second threshold voltage of the first cell string, and a second location in the one direction of a ground select transistor programmed with the second threshold voltage of the second cell string.

According to embodiments of the present disclosure, there is provided a memory cell array including at least one memory block including a plurality of cell strings, each of the plurality of cell strings being connected to one or more word lines and a plurality of ground selection lines arranged in one direction, wherein the plurality of cell strings include a first cell string and a second cell string, and a control logic configured to control at least one of a program operation or a read operation for the memory cell array, wherein a part of a plurality of ground select transistors respectively connected to the plurality of ground selection lines is programmed with a first threshold voltage, and other parts of the plurality of ground select transistors are programmed with a second threshold voltage different from the first threshold voltage, wherein a first memory cell included in the first cell string and a second memory cell included in the second cell string are connected to the one or more word lines, and wherein a number of bits of data stored in the first memory cell is different from a number of bits of data stored in the second memory cell based on a difference between a first location in the one direction of the ground select transistor programmed with the second threshold voltage of the first cell string, and a second location in the one direction of a ground select transistor programmed with the second threshold voltage of the second cell string.

According to embodiments of the present disclosure, there is provided a memory device including a memory cell array including at least one memory block including a plurality of cell strings, each of the plurality of cell strings being connected to one or more word lines arranged in one direction and a plurality of ground selection lines, wherein the plurality of cell strings include a first cell string and a second cell string, and a control logic configured to control at least one of a program operation or a read operation for the memory cell array, wherein a part of the plurality of ground select transistors respectively connected to the plurality of ground selection lines is programmed with a first threshold voltage, and other parts of the plurality of ground selection lines are programmed with a second threshold voltage different from the first threshold voltage, wherein a number of memory cells in which user data is stored in the first cell string is different from a number of memory cells in which user data is stored in the second cell string based on a difference between a first location in the one direction of a ground select transistor programmed with the second threshold voltage in the first cell string, and a second location in the one direction of a ground select transistor programmed with the second threshold voltage of the second cell string, wherein a first memory cell included in the first cell string and a second memory cell included in the second cell string are connected to one of the one or more word lines, and wherein a number of bits of data stored in the first memory cell is different from a number of bits of data stored in the second memory cell based on a difference between the first location and the second location.

According to embodiments of the present disclosure, the number of memory cells that store user data and are included in each of cell strings may vary depending on locations in one direction of ground select transistors programmed with a second threshold voltage in the GSL Coded structure, thereby ensuring data storage stability and integration of memory devices.

According to embodiments of the present disclosure, the number of bits of data stored in each of memory cells may vary depending on locations in one direction of ground select transistors programmed with a second threshold voltage in the GSL Coded structure, thereby ensuring data storage stability and integration of memory devices.

The effect that is obtained from the present disclosure is not limited to the above. The technical effect not mentioned above may be explicitly known to those skilled in the art from the description below.

### BRIEF DESCRIPTION OF DRAWINGS

FIG. 1 is a block diagram illustrated to explain a memory system according to embodiments of the present disclosure;

FIG. 2 is a block view illustrated to explain a memory device according to embodiments of the present disclosure;

FIG. 3 is a circuit view illustrated to explain a memory block according to embodiments of the present disclosure;

FIG. 4A and FIG. 4B are view illustrated to explain a structure of a memory block according to embodiments of the present disclosure;

FIG. 5A is a view illustrated to explain a threshold voltage of ground select transistor according to embodiments of the present disclosure;

FIG. 5B is a view illustrated to explain an example in which a threshold voltage distribution of ground select transistors changes according to embodiments of the present disclosure;

FIG. 6A is a view illustrated to explain a structure of a memory block according to embodiments of the present disclosure;

FIG. 6B is a view illustrated to briefly explain a structure of a memory block of FIG. 6A;

FIG. 7A is a view illustrated to explain a structure of a memory block according to embodiments of the present disclosure;

FIG. 7B is a view illustrated to briefly explain a structure of a memory block of FIG. 7A;

FIG. 8A is a view illustrated to explain a structure of a memory block according to embodiments of the present disclosure;

FIG. 8B is a view illustrated to briefly explain a structure of a memory block of FIG. 8A;

FIG. 9A is a view illustrated to explain a structure of a memory block according to embodiments of the present disclosure;

FIG. 9B is a view illustrated to briefly explain a structure of a memory block of FIG. 9A;

FIG. 10A and FIG. 10B are views illustrated to explain states of memory cells according to embodiments of the present disclosure;

FIG. 11A, FIG. 11B, FIG. 11C, FIG. 11D, and FIG. 11E are views illustrated to explain a structure of a memory block according to various embodiments of the present disclosure;

FIG. 12 is a view illustrated to explain states of memory cells according to embodiments of the present disclosure;

FIG. 13A and FIG. 13B are view illustrated to explain a structure of a memory block according to various embodiments of the present disclosure;

FIG. 14 is a flowchart illustrating an operation method of a memory device according to embodiments of the present disclosure;

FIG. 15 is a cross-sectional view illustrating a memory device having a B-VNAND structure according to embodiments of the present disclosure; and

FIG. 16 is a block view illustrating an example where a memory device is applied to an SSD system according to embodiments of the present disclosure.

### DETAILED DESCRIPTION

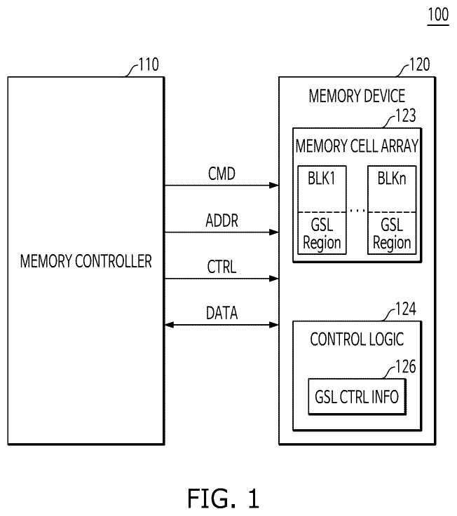

Embodiments of the technical spirit of the present disclosure will be described in detail with reference to FIG. 1 to FIG. 16. Like reference numerals in the drawings denote like elements, and the redundant description will be omitted.

FIG. 1 is a block view illustrated to explain a memory system 100 according to embodiments of the present disclosure.

Referring to FIG. 1, a memory system 100 may include a memory controller 110 and a memory device 120. The memory device 120 may include a memory cell array 123 and a control logic 124. Although not shown in FIG. 1, the memory device 120 may further include a voltage generator that generates various voltages associated with programming, reading or erasing of data, a page buffer connected to the memory cell array 123 through bit lines, and other elements.

According to embodiments of the present disclosure, a memory device 120 may include a non-volatile memory device. As an example, the memory device 120 may include a non-volatile memory device such as a NAND Flash Memory, a Vertical NAND Flash Memory, a NOR Flash Memory, a Resistive Random Access Memory, a Phase-Change Memory, a Magnetoresistive Random Access Memory, etc. According to embodiments, the memory device 120 or the memory system 100 may be implemented as an internal memory embedded in an electronic device, or may be implemented as an external memory removable from the electronic device. As an example, the memory device 120 or memory system 100 may be implemented in various forms, such as a Universal Flash Storage (embedded UFS) memory device, an embedded Multi-Media Card (eMMC), a Solid State Drive (SSD), a UFS memory card, a Compact Flash (CF), a Secure Digital (SD), a Micro Secure Digital (Micro-SD), a Mini Secure Digital (Mini-SD), an extreme Digital (xD), a Memory Stick, etc.

The memory controller 110 may control the memory device 120 to read data stored in the memory device 120 or write (or, program) data in the memory device 120 in response to writing/reading requests from a host (not shown). The memory controller 110 may provide an address ADDR and a command CMD to the memory device 120 to control at least one of the program operation, the reading operation or the erasing operation on the memory device 120. The memory device 120 may receive a control signal CTRL from the memory controller 110. Data DATA to be written on the memory device 120 and data DATA read from the memory device 200 may be transmitted between the memory controller 110 and the memory device 120.

The memory cell array 123 may include a plurality of memory blocks BLK1 to BLKn (where n is a natural number equal to or greater than two (2)), and each of the BLK1 to BLKn may include a plurality of memory cells. When the memory device 120 is a vertical NAND flash memory device, each of the memory blocks BLK1 to BLKn may include a plurality of cell strings. For example, a plurality of cell strings may be connected to any one of bit lines. During the data program operation or the reading operation, any one cell string selected from among the plurality of cell strings may be electrically connected to a bit line.

According to embodiments, each of the plurality of cell blocks BLK1 to BLKn may include a GSL region in which a plurality of ground selection lines are arranged. For example, a first cell block BLK1 and an nth cell block BLKn each may include the GSL region. In the manufacturing process of the memory device 120, each of the plurality of ground select transistors arranged in the GSL region included in each of the plurality of cell blocks BLK1 to BLKn may be programmed to have a predetermined threshold voltage. For example, a part of the plurality of ground select transistors may be programmed with a first threshold voltage, and other parts of the plurality of ground select transistors may be programmed with a second threshold voltage different from the first threshold voltage.

According to embodiments of the present disclosure, the control logic 124 may include GSL control information 126. For example, the control logic 124 may include a predetermined storage circuit that non-volatilely stores information on a fuse circuit, an anti-fuse circuit, etc., and control the program operation on the plurality of ground select transistors included in each of the plurality of cell blocks BLK1 to BLKn based on the GSL control information 126. During the manufacturing process of the memory device 120, the GSL control information 126 may be implemented to be stored in a storage circuit outside the control logic 124, and the GSL control information 126 may be provided to the control logic 124 at the initial stage of the driving process.

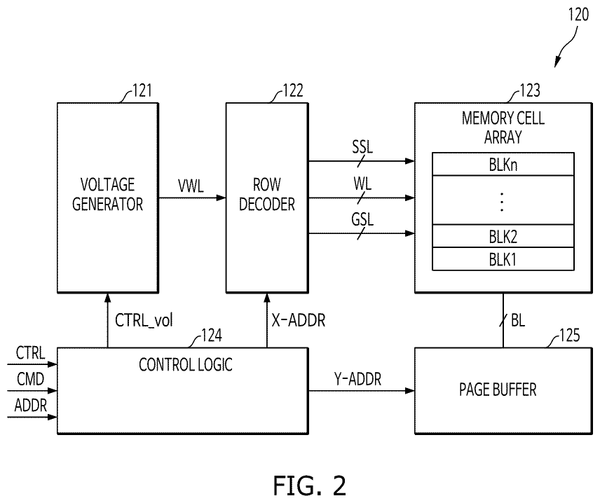

FIG. 2 is a block view illustrated to explain a memory device 120 according to embodiments of the present disclosure.

Referring to FIG. 2, a memory device 120 may include a memory cell array 123, a voltage generator 121, a row decoder 122, a control logic 124, and a page buffer 125. Although not shown in FIG. 2, the memory device 120 may further include various elements such as a data input and output circuit, an input and output interface, etc.

The memory cell array 123 may be connected to word lines WL, string selection lines SSL, ground selection lines GSL, and bit lines BL. Specifically, the memory cell array 123 may be connected to a row decoder 122 through the word lines WL, the string selection lines SSL, and the ground selection lines GSL, and may be connected to a page buffer 125 through the bit lines BL. The memory cell array 123 may include the plurality of memory blocks BLK1 to BLKn (where n is a natural number greater than or equal to two (2)).

Each of the plurality of memory blocks BLK1 to BLKn may include a plurality of memory cells and a plurality of select transistors. The plurality of memory cells may be connected to the word lines WL, and the plurality of select transistors may be connected to the string selection lines SSL or the ground selection lines GSL. Each of the plurality of memory cells may store one or more bits. For example, the memory cell may be a single level cell (referred to as ‘SLC’) that stores one (1) bit of data. For another example, the memory cell may be a multi-level cell (referred to as MLC) that stores two (2) bits of data. For another example, the memory cell may be a triple-level cell (referred to as TLC) that stores three (3) bits of data. For yet another example, the memory cell may be a quad-level cell (referred to as QLC) that stores four (4) bits of data. However, the present disclosure is not limited thereto, but the memory cell may store five (5) or more bits of data.

The row decoder 122 may be connected to the memory cell array 123 through the string selection lines SSL, the word lines WL, and the ground selection lines GSL. During a program operation or a read operation, the row decoder 122 may determine one of the word lines WL as a selected word line based on a row address X_ADDR provided from the control logic 124, and may determine the other word lines as non-selected word lines. For example, during a program operation, the row decoder 122 may apply a program voltage or a program verification voltage to the selected word line, and during a read operation, may apply a read voltage to the selected word line. During the program operation or the reading operation, the row decoder 122 may determine one of the string selection lines SSL as a selected string selection line based on the row address X_ADDR provided from the control logic 124, and other string selection lines as non-selected string selection lines. During the program operation or the reading operation, the row decoder 122 may determine a part of the ground selection lines GSL as selected ground selection lines based on the row address X_ADDR provided from the control logic 124, and other ground selection lines as non-selected ground selection lines.

The control logic 124 may control various operations in the memory device 120 overall. For example, the control logic 124 may output various internal control signals to program data to the memory cell array 123, and read data from the memory cell array 123 based on the command CMD, the address ADDR and the control signal CTRL. Various internal control signals output from the control logic 124 may be provided to the row decoder 122, the page buffer 125, and the voltage generator 121. For example, the control logic 124 may provide the row address X_ADDR to the row decoder 122, and a column address Y_ADDR to the page buffer 125, and a voltage control signal CTRL_vol to the voltage generator 121.

The voltage generator 121 may generate various types of voltages to perform a program operation, a read operation, or an erase operation for the memory cell array 123 in response to receiving the voltage control signal CTRL_vol. The voltage generator 121 may generate the word line voltage VWL, for example, a program voltage, a program verification voltage, a verification voltage, a read voltage, a pass voltage, an erase voltage, an erase verification voltage, etc. Referring to FIG. 2, the voltage generator 121 is being illustrated to generate the word line voltage VWL, but the word line voltage VWL may refer to a voltage provided to the string selection lines SSL or the ground selection lines GSL in addition to a voltage provided to the word lines WL connected to the memory cell array 123.

The control logic 124 may control a voltage level for coding of the GSL region included in each of the plurality of cell blocks BLK1 to BLKn. For example, under the control of the control logic 124, a program operation may be performed so that a first threshold voltage of the ground select transistors corresponding to a part of the plurality of ground select transistors respectively connected to the ground selection lines GSL, and a second threshold voltage of the ground select transistors corresponding the other parts of the plurality of ground select transistors may have different levels. The control logic 124 may control a voltage adjustment operation to adjust a threshold voltage level for dummy cells disposed between the ground select transistors and the memory cells.

The page buffer 125 may be connected to the memory cell array 123 through the bit lines BL. The page buffer 125 may select at least one of the bit lines BL based on the column address Y_ADDR provided from the control logic 124. The page buffer 125 may operate as a write driver or a sensing amplifier according to operation modes. For example, during the program operation, the page buffer 125 may apply a bit line voltage corresponding to the data to be programmed to the selected bit line. During the read operation, the page buffer 125 may detect the current or the voltage of the selected bit line to detect the data stored in the memory cell.

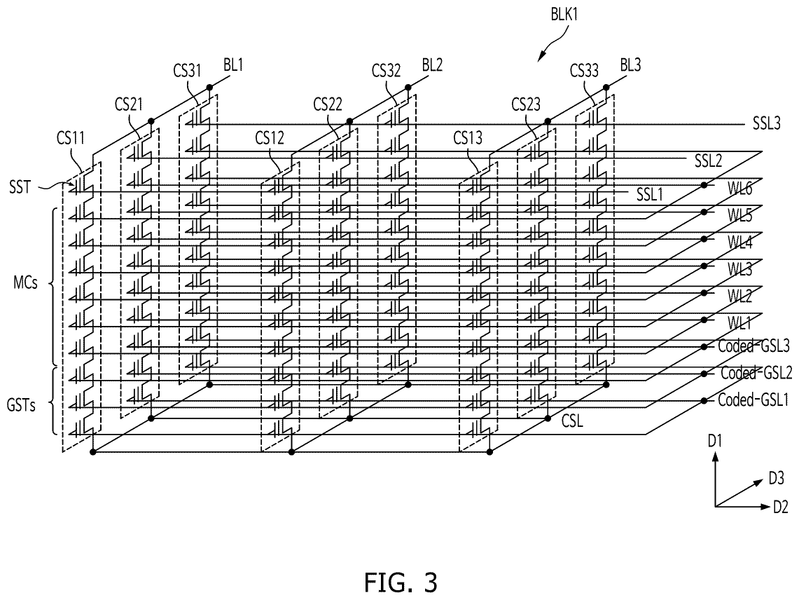

FIG. 3 is a circuit view illustrated to explain a memory block BLK1 according to embodiments of the present disclosure.

Referring to FIG. 3, the memory block BLK1 may include cell strings CS11 to CS33, word lines WL1 to WL6, bit lines BL1 to BL3, string selection lines SSL1 to SSL3, a common source line CSL, and programmed ground selection lines Coded-GSL1 to Coded-GSL3. Each of the cell strings CS11 to CS33 may be arranged along a second direction D2 or a third direction D3 to form rows or columns.

Each of the cell strings (e.g., CS11) may include a string select transistor SST, memory cells MCs, and ground select transistors GSTs connected in series. According to an exemplary embodiment, the select transistors SST and GSTs and the memory cells MCs included in each of the cell strings may form a stacked structure on a substrate along a first direction D1.

Each of the columns of the cell strings CS11 to CS33 may be connected to bit lines BL1 to BL3 different from one another and arranged along the second direction D2. For example, the string select transistors SST included in cell strings CS11, CS21 and CS31 may be jointly connected to a bit line BL1. In addition, the string select transistors SST included in cell strings CS12, CS22 and CS32 may be commonly connected to a bit line BL2. In addition, the string select transistors SST included in cell strings CS13, CS23 and CS33 may be jointly connected to a bit line BL3.

Each of the rows of the cell strings CS11 to CS33 may be connected to string selection lines SSL1 to SSL3 different from one another and arranged along the third direction D3. For example, the string select transistors SST included in cell strings CS11, CS12 and CS13 may be jointly connected to a string selection line SSL1. In addition, the string select transistors SST included in cell strings CS21, CS22 and CS23 may be jointly connected to a string selection line SSL2. In addition, the string select transistors SST included in cell strings CS31, CS32 and CS33 may be jointly connected to a string selection line SSL3.

The memory cells placed at the same height may be commonly connected to one word line, and the memory cells placed at the different heights may be connected to word lines different from each other and arranged along the first direction, respectively. The ground select transistors placed at the same height may be commonly connected to the one programmed ground selection line, and the ground select transistors placed at the different heights may be connected to the ground selection lines different from each other and arranged along the first direction D1, respectively.

The cell strings CS11 to CS33 may be commonly connected to the common source line CSL. For example, the ground select transistor placed at the lowest height among the ground select transistors included in each of the cell strings CS11 to CS33 may be connected to the common source line CSL.

The memory block BLK1 of FIG. 3 is merely exemplary, and the present disclosure is not limited the memory block BLK1 of FIG. 3. For example, the number of rows of cell strings may be increased or reduced. As the number of rows of cell strings is changed, the number of string selection lines connected to the rows of the cell strings or the number of cell strings connected to one bit line may change. For another example, the number of columns of cell strings may be increased or reduced. As the number of columns of cell strings changes, the number of bit lines connected to the columns of cell strings or the number of cell strings connected to one string selection line may change.

According to embodiments, at least one or more dummy cells may be provided between the string select transistor SST and the memory cells MCs in each of the cell strings. At least one or more dummy cells may be provided between the memory cells MCs and the ground select transistors GSTs in each of the cell strings. One or more dummy cells may be provided between the respective memory cells MCs. The dummy cells may have the same structure as the memory cells MCs. The dummy cells may not be programmed (e.g., banned to be programmed) or may be programmed differently from the memory cells MCs. For example, when the memory cells MCs are programmed to have two (2) or more threshold voltage distributions, the dummy cells may be programmed to have one threshold voltage distribution or a smaller number of threshold voltage distributions than the memory cells MCs. A part of the dummy cells may be programmed to be the same as the memory cell MCs.

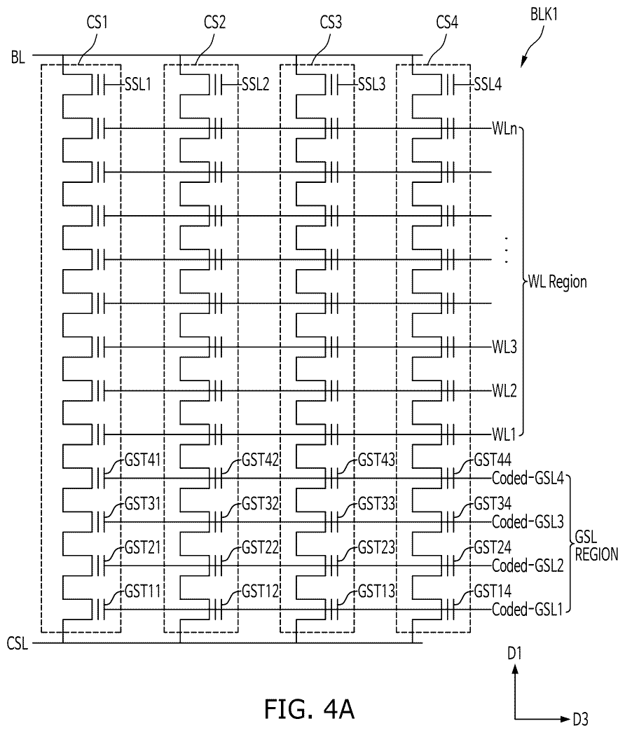

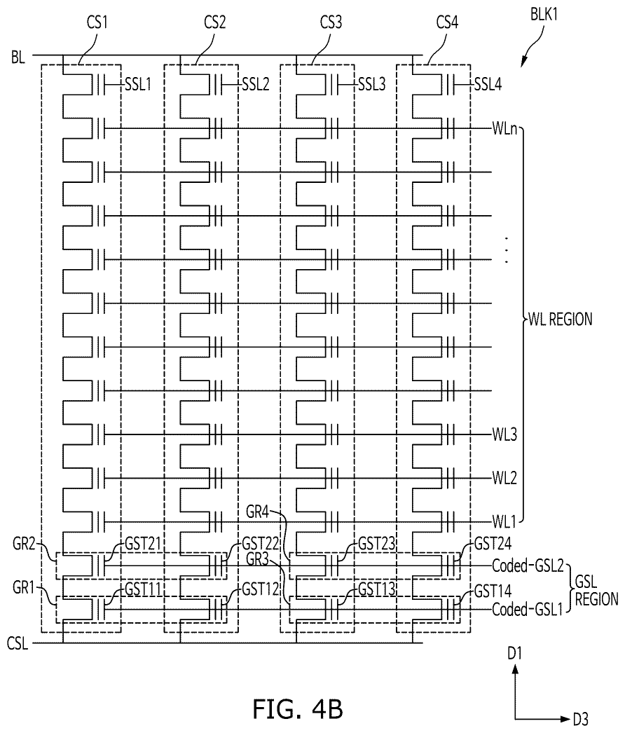

FIG. 4A is a view illustrated to explain the structure of a memory block BLK1 according to embodiments of the present disclosure.

Referring to FIG. 4A, the memory block BLK1 may include a plurality of cell strings CS1 to CS4. The plurality of cell strings CS1 to CS4 may be connected to a bit line BL, a plurality of string selection lines SSL1 to SSL4, a plurality of word lines WL1 to WLn (where n is a natural number), a plurality of programmed ground selection lines Coded-GSL1 to Coded-GSL4, and a common source line CSL. For example, a first cell string CS1 may be connected to a first string selection line SSL1, a first word line to an nth word line WL1 to WLn, first to fourth programmed ground selection lines Coded-GSL1 to Coded-GSL4, and the common source line CSL. As another example, a second cell string CS2 may be connected to a second string selection line SSL2, the first word line to the nth word line WL1 to WLn, the first to fourth programmed ground selection lines Coded-GSL1 to Coded-GSL4, and the common source line CSL.

The structure of the ground selection lines illustrated in FIG. 4A may be referred to as a Ground Selection Line (Coded GSL) structure. In addition, a region to which the Coded GSL structure is applied may be referred to as a GSL region GSL Region. As illustrated, a word line region WL Region may be placed on the upper side of the GSL region GSL Region. However, the present disclosure is not limited thereto. The Coded GSL structure may indicate a structure that controls the connection between a channel and the common source line CSL by using at least two or more ground selection lines connected to ground select transistors having different threshold voltage distributions. For example, at least part of the first to fourth programmed ground selection lines (Coded-GSL1 to Coded-GSL4) may be connected to ground select transistors having different threshold voltage distributions.

According to embodiments, a first programmed ground selection line Coded-GSL1 may be connected to ground select transistors GST11 to GST14, a second programmed ground selection line Coded-GSL2 may be connected to ground select transistors GST21 to GST24, a third programmed ground selection line Coded-GSL3 may be connected to ground select transistors GST31 to GST34, and a fourth programmed ground selection line Coded-GSL4 may be connected to ground select transistors GST41 to GST44.

According to an exemplary embodiment, a part of the ground select transistors GST11 to GST14 connected to the first programmed ground selection line Coded-GSL1 may be programmed with a first threshold voltage, and other parts of the ground select transistors GST11 to GST14 may be programmed with a second threshold voltage different from the first threshold voltage. For example, a ground select transistor GST14 may be programmed with the second threshold voltage, and ground select transistors GST11 to GST13 may be programmed with the first threshold voltage. In addition, a ground select transistor GST23 among the ground select transistors GST21 to GST24 connected to the second programmed ground selection line Coded-GSL2 may be programmed with the second threshold voltage, and the ground select transistors GST21, GST22 and GST24 may be programmed with the first threshold voltage. In the same manner, a ground select transistor GST32 among ground select transistors GST31 to GST34 connected to the third programmed ground selection line Coded-GSL3 may be programmed with the second threshold voltage, and the ground select transistors GST31, GST33 and GST34 may be programmed with the first threshold voltage. A ground select transistor GST41 among the ground select transistors GST41 to GST44 connected to a fourth programmed ground selection line Coded-GSL4 may be programmed with the second threshold voltage, and the ground select transistors GST42 to GST44 may be programmed with the first threshold voltage.

A specific cell string among the cell strings CS1 to CS4 connected to the common source line CSL may be selected depending on the voltage applied to the programmed ground selection lines Coded-GSL1 to Coded-GSL4.

As an example, the first threshold voltage may be 3 V and the second threshold voltage may be 0 V. When a fourth cell string CS4 is selected, a voltage of 2 V (a voltage between the first threshold voltage and the second threshold voltage) may be applied to the first programmed ground selection line Coded-GSL1, and a voltage of 6 V (a voltage higher than the first threshold voltage and the second threshold voltage) may be applied to the second to fourth programmed ground selection lines Coded-GSL2 to Coded-GSL4. Therefore, a ground select transistor GST14 having the second threshold voltage among the ground select transistors GST11 to GST14 connected to the first programmed ground selection line Coded-GSL1 may be turned on, but the ground select transistors GST11 to GST13 having the first threshold voltage may be turned off. Accordingly, the fourth cell string CS4 may be connected to the common source line CSL, but first to third cell strings CS1 to CS3 may not be connected to the common source line CSL.

As another example, the first threshold voltage may be 0 V and the second threshold voltage may be 3 V. When the fourth cell string CS4 is selected, a voltage of 6 V (a voltage higher than the first and second threshold voltages) may be applied to the first programmed ground selection line Coded-GSL1, and a voltage of 2 V (a voltage between the first and second threshold voltages) may be applied to the second to fourth programmed ground selection lines Coded-GSL2 to Coded-GSL4. Therefore, all of the ground select transistors GST11 to GST14 connected to the first programmed ground selection line Coded-GSL1 may be turned on, and ground select transistors GST23, GST32 and GST41 having the second threshold voltage among the ground select transistors connected to the second to fourth programmed ground selection lines Coded-GSL2 to Coded-GSL4 may be turned off. Accordingly, the fourth cell string CS4 may be connected to the common source line CSL, but the first to third cell strings CS1 to CS3 may not be connected to the common source line CSL. For convenience of explanation, an example in which the second threshold voltage is higher than the first threshold voltage is described. However, the present disclosure is not limited thereto.

Although not shown in FIG. 4A, one or more dummy lines may be arranged between the string selection lines SSL1 to SSL4 and the word lines WL1 to WLn, between the word lines WL1 to WLn and the programmed ground selection lines Coded-GSL1 to Coded-GSL4, and/or between the programmed ground selection lines Coded-GSL1 to Coded-GSL4 and the common source line CSL. In addition, one or more dummy lines may be arranged between the word lines WL1 to WLn and/or between the programmed ground selection lines Coded-GSL1 to Coded-GSL4. Interference between adjacent transistors in the first direction D1 may be reduced by placing the dummy lines. As a result, the performance of the memory device may be improved.

According to embodiments, the string selection lines SSL1 to SSL4, the word lines WL1 to WLn, the programmed ground selection lines Coded-GSL1 to Coded-GSL4 and the common source line CSL may be arranged in the first direction D1 in the memory block BLK1. In addition, the number of memory cells in which user data included in each of the plurality of cell strings CS1 to CS4 is stored may be different according to the positions of ground select transistors programmed with the second threshold voltage in the first direction D1). For example, when a dummy line is placed on the top of the fourth programmed ground selection line Coded-GSL4, a dummy cell in which user data is not stored may be placed on the top of the ground select transistor GST41 programmed with the second threshold voltage, and a memory cell in which user data is stored may be placed on the top of the ground select transistors GST42 to GST44 programmed with the first threshold voltage.

A high voltage such as a program voltage (around 20V) or a pass voltage may be applied to a word line in a NAND flash memory, which instantly increases a channel

field rapidly to cause a large change in voltage potential. The rapid potential change that occurs due to applying a high voltage to the word line may increase the possibility of the hot carrier occurrence in the ground select transistor GST41 programmed with the second threshold voltage, which affects the stability of the Coded GSL structure. The hot carrier effect indicates a phenomenon in which electrons or holes accelerated by a high electric field cross a boundary to be trapped in a gate oxide film or damage the oxide film itself. Therefore, a threshold voltage may be changed or a current leakage may be increased to cause performance deterioration and shorten the lifespan of devices.

According to embodiments, a dummy cell in which user data is not stored may be placed on the top of the ground select transistor programmed with the second threshold voltage to reduce the damage caused by the hot carrier injection and minimize the effects of degradation. In addition, a memory cell that stably stores user data in an environment with low risk of hot carrier occurrence on the top of the ground select transistor programmed with the first threshold voltage. The arrangement of the memory cells according to the Coded GSL structure may enhance the data storage stability and improve the integration of the memory device.

FIG. 4B is a view illustrated to explain the structure of the memory block BLK1 according to embodiments of the present disclosure.

Referring to FIG. 4B, a plurality of cell string CS1 to CS4 may be divided into two (2) groups in the Coded GSL structure. For example, a first cell string CS1 and a second cell string CS2 may be grouped into one group, and a third cell string CS3 and a fourth cell string CS4 may be grouped into another group.

Each of the plurality of cell strings CS1 to CS4 may include ground select transistors connected to two (2) programmed ground selection lines Coded-GSL1 and Coded-GSL2. Ground select transistors included in the same group of cell strings and connected to the same programmed ground selection line among the plurality of ground select transistors GST11 to GST24 may be grouped into one group and programmed to have the same threshold voltage distribution. In addition, a part of the group of ground select transistors connected to one programmed ground selection line may be programmed with the first threshold voltage, and other parts of the group of ground select transistors may be programmed with the second threshold voltage. For example, ground select transistors GST11 and GST12 may be grouped into a first group GR1 and programmed with the first threshold voltage. In addition, ground select transistors GST21 and GST22 may be grouped into a second group GR2 and programmed with the second threshold voltage. In addition, ground select transistors GST13 and GST14 may be grouped into a third group GR3 and programmed with the second threshold voltage. The ground select transistors GST23 and GST24 may be grouped into a fourth group GR4 and programmed with the first threshold voltage.

Therefore, a cell string from a specific group of the cell strings CS1 to CS4 connected to the common source line CSL may be selected depending on the voltage applied to the programmed ground selection lines Coded-GSL1 to Coded-GSL2.

FIG. 4A illustrates an example where four (4) cell strings are grouped into four (4) groups, and FIG. 4B illustrates an example where four (4) cell strings are grouped into two (2) groups, but the present disclosure is not limited thereto. Therefore, the memory blocks according to embodiments may include more numbers of cell strings, and the plurality of cell strings may be grouped into N groups (where N is a natural number equal to or greater than two (2)) to form the Coded GSL structure that is electrically separated. Each of the plurality of cell strings may include N ground select transistors respectively connected to N programmed ground selection line, and one of N ground select transistors may be programmed with the first threshold voltage, and the other ground select transistor may be programmed with the second threshold voltage.

According to embodiments, the number of memory cells that store user data, which are included in each of cell strings the same group may be the same. Additionally, or differently, the number of bits of data stored in each of the memory cells that user data, which are included in each of the cell strings in the same group may be the same. This is because the locations of the ground select transistors programmed with the second threshold voltage included in each of the cell strings included in the same group in the first direction D1 may be the same.

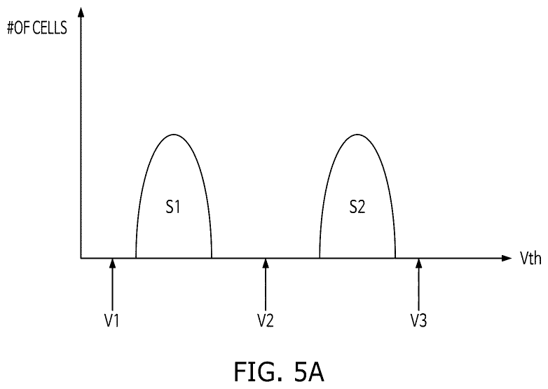

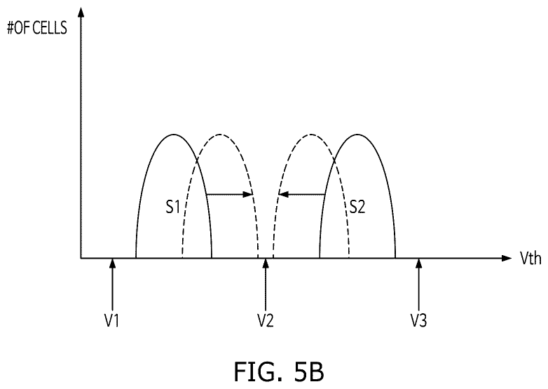

FIG. 5A is a view illustrated to explain threshold voltages of ground select transistors according to embodiments of the present disclosure.

Referring to FIG. 5A, the ground select transistors may include a first threshold voltage distribution S1 or a second threshold voltage distribution S2. The first threshold distribution S1 may indicate a threshold voltage distribution ranging from a first voltage level V1 to a second voltage level V2, and the second threshold voltage distribution S2 may indicate a threshold voltage distribution ranging from a second voltage level V2 to a third voltage level V3. For example, when the voltage at the second voltage level V2 is applied to the transistor having the first threshold voltage distribution S1, the transistor having the first threshold voltage distribution S1 may be turned on. When the voltage at the second threshold voltage level V2 is applied to the transistor having the second threshold voltage distribution S2, the transistor having the second threshold voltage level S2 may be turned off. When the voltage at the third voltage level V3 is applied to the transistor having the first threshold voltage distribution S1 or the transistor having the second threshold voltage distribution S2, the transistor having the first threshold voltage distribution S1 or the transistor having the second threshold voltage distribution S2 may be turned on.

The control logic may control the memory device so that any one of the first voltage level V1, the second voltage level V2 or a third voltage level V3 is applied to the programmed ground selection lines for controlling the ground select transistors connected to the programmed ground selection lines. For example, the first voltage level V1 may be 0V, the second voltage level V2 may be 2V, and the third voltage level V3 may be 6V. When the voltage of 2V is applied to the programmed ground selection line connected to the select transistors, the ground select transistors having the first threshold voltage distribution S1 may be turned on, but the transistors having the second threshold voltage distribution S2 may be turned off.

FIG. 5B is a view illustrated to explain a change of a threshold voltage distribution of ground select transistors according to embodiments of the present disclosure.

Referring to FIG. 5B, the ground select transistors included in a memory block may be interfered with the program operation or the read operation on the adjacent transistors. For example, the ground select transistors may be interfered with the program operation or the read operation on the adjacent transistors in a first direction (e.g., direction D1 of FIG. 4A). The threshold voltage level of the ground select transistor having a relatively low threshold voltage may be increased by the interference above.

The ground select transistor having a relatively high threshold voltage level may have a threshold voltage level lowered due to charge leakage, etc. For example, as shown in FIG. 5B, when gaps between the ground select transistors programmed with the first threshold voltage, and the ground select transistors programmed with the second threshold voltage become narrow, the electrical characteristic of the ground selection lines may be reduced, thereby reducing data reliability.

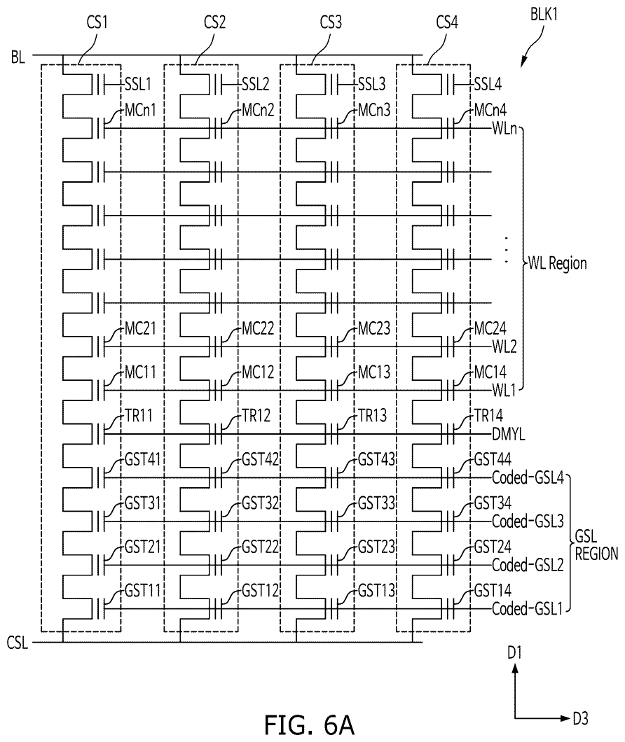

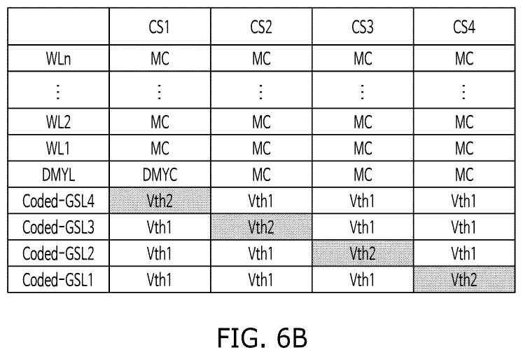

FIG. 6A is a view illustrated to explain the structure of a memory block BLK1 according to embodiments. The memory block BLK1 of FIG. 6A may correspond to the modification to the memory block BLK1 of FIG. 4A.

Referring to FIG. 6A, the memory block BLK1 may include a plurality of cell strings CS1 to CS4. The plurality of cell strings CS1 to CS4 may be connected to a bit line BL, a plurality of string selection lines SSL1 to SSL4, a plurality of word lines WL1 to WLn, a plurality of programmed ground selection lines Coded-GSL1 to Coded-GSL4, and a common source line CSL. Memory cells MC11 to MCn4 that store user data, which are included in each of the plurality of cell strings CS1 to CS4 may be connected to the plurality of word lines WL1 to WLn.

The memory block BLK1 may further include a dummy line DMYL arranged between a word line region WL Region and a GSL region GSL Region. The dummy line DMYL may be connected to the plurality of cell strings CS1 to CS4. The dummy line DMYL may be connected to transistors TR11 to TR14 arranged between the word line region WL Region and the GSL region GSL Region in each of the plurality of cell strings CS1 to CS4.

The transistors TR11 to TR14 connected to the dummy line DMYL may be dummy cells where user data is not stored, or memory cells in which user data is stored. A part of the transistors TR11 to TR14 may be used as a memory cell where user data is stored according to the locations in the first direction D1 of the ground select transistors programmed with the second threshold voltage in the GSL region GSL Region to which CSL coding is applied, and other parts of the transistors TR11 to TR14 may be used as a dummy cell in which user data is not stored. Therefore, the number of memory cells in which user data included in each of the plurality of cell strings CS1 to CS4 may vary depending on the locations in the first direction D1 of the ground select transistors programmed with the second threshold voltage. However, the present disclosure is not limited thereto, but at least part of the cell strings in the memory block BLK1 may include the same number of memory cells.

According to an exemplary embodiment, among ground select transistors GST11, GST21, GST31 and GST41 included in a first cell string CS1, a ground select transistor GST41 may be programmed with the second threshold voltage, and among ground select transistors GST12, GST22, GST32 and GST42 included in a second cell string CS2, a ground select transistor GST32 may be programmed with the second threshold voltage. However, the present disclosure is not limited thereto.

A transistor TR11 adjacent to the ground select transistor GST41 in the first direction D1 may be used as a dummy cell in which user data is not stored, and a transistor TR12 adjacent to the ground select transistor GST32 in the first direction D1 may be used as a memory cell in which user data is stored. Depending on the locations of the ground select transistor GST41 in the first direction D1 and the ground select transistor GST32 in the first direction D1, the number of memory cells in which user data is stored in each of the first cell string CS1 and the second cell string CS2 may vary.

According to embodiments, the number of memory cells that store user data included in the cell string may vary depending on the distance between the location of the ground select transistor programmed with the second threshold voltage in the first direction D1 and a predetermined line. The closer the distance between the location of the ground select transistor programmed with the second threshold voltage in the first direction D1 and a predetermined line, the greater the number of memory cells that store the user data included in the cell string. The predetermined line may be the common source line CSL, but the present disclosure is not limited thereto. The predetermined line may be any line extending in the third direction D3 and disposed at the bottom of the GSL region.

According to an embodiment where the ground select transistors GST41 and GST32 are programmed with the second threshold voltage, the distance from the common source line CSL to the location of the ground select transistor GST32 in the first direction D1 may be shorter than the distance from the common source line CSL to the location of the ground select transistor GST41 in the first direction D1. Therefore, the number of memory cells in which user data included in the second cell string CS2 is stored may be greater than the number of memory cells in which user data included in the first cell string CS1 is stored. In other words, among the transistors TR11 and TR12 connected to the dummy line DMYL, the transistor TR11 may be used as a dummy cell in which user data is not stored, and the transistor TR12 may be used as a memory cell in which user data is stored. Therefore, the number of memory cells in which user data is stored included in the second cell string CS2 may be greater than the number of memory cells in which user data is stored included in the first cell string CS1.

FIG. 6B is view illustrated to briefly explain the structure of the memory block of FIG. 6A. The table of FIG. 6B briefly illustrates information on transistors connected to each line in the memory block BLK1 of FIG. 6A. For example, a transistor (MC11 of FIG. 6A) included in the first cell string CS1 and connected to the first word line WL1 may be a memory cell MC in which user data is stored, and a transistor (TR11 of FIG. 6A) included in the first cell string CS1 and connected to the dummy line DMYL may be a dummy cell DMYC in which user data is not stored. A transistor (GST41 of FIG. 6a) included in the first cell string CS1 and connected to the fourth programmed ground selection line Coded-GSL4 may be a ground select transistor programmed with a second threshold voltage Vth2, and a transistor (GST31 of FIG. 6a) included in the first cell string CS1 and connected to the third programmed ground selection line Coded-GSL3 may be a ground select transistor programmed with a first threshold voltage Vth1.

Referring to FIG. 6B, the dummy line DMYL may be placed between a plurality of word lines WL1 to WLn and a plurality of programmed ground selection lines Coded-GSL1 to Coded-GSL4. Transistors connected to the dummy line DMYL may be used as a dummy cell DMYC in which user data is not stored or a memory cell MC in which user data is stored.

According to embodiments, a transistor disposed on the upper end adjacent to the ground select transistor programmed with the second threshold voltage Vth2 among the transistors connected to the dummy line DMYC may be used as the dummy cell DMYC in which user data is not stored. However, a ground select transistor may be an exception. Other transistors may be used as the memory cell MC that stores the user data. A transistor included in the first cell string CS1 among the transistors connected to the dummy line DMYL may be used as the dummy cell DMYC, and the transistors included in the second cell string to the fourth cell string CS2 to CS4 may be used as the memory cell MC. However, the present disclosure is not limited thereto. For example, a transistor disposed at the top first adjacent to the ground select transistor programmed with the second threshold voltage Vth2 and a transistor disposed at the top second adjacent to the programmed ground select transistor (e.g., a transistor with a distance of two spaces at the top based on the table), among the transistors connected to the dummy line DMYC, may be used as the dummy cell DMYC. Accordingly, the transistors included in the first cell string CS1 and the second cell string CS2 among the transistors connected to the dummy line DMYL may be used as the dummy cells DMYC, and the transistors included in the third cell string CS3 and the fourth cell string CS4 may be used as the memory cells MC.

The number of memory cells that store user data of the cell string may vary depending on the location of the ground select transistor programmed with the second threshold voltage Vth2 in the cell string in the first direction (e.g., direction D1 of FIG. 6A).

According to an embodiment in FIG. 6B, other strings than a transistor disposed at the top adjacent to the ground select transistor programmed with the second threshold voltage Vth2, among the transistors connected to the dummy line DMYC, may be used as the memory cell MC that stores the user data. Therefore, the integration of the memory device may be enhanced.

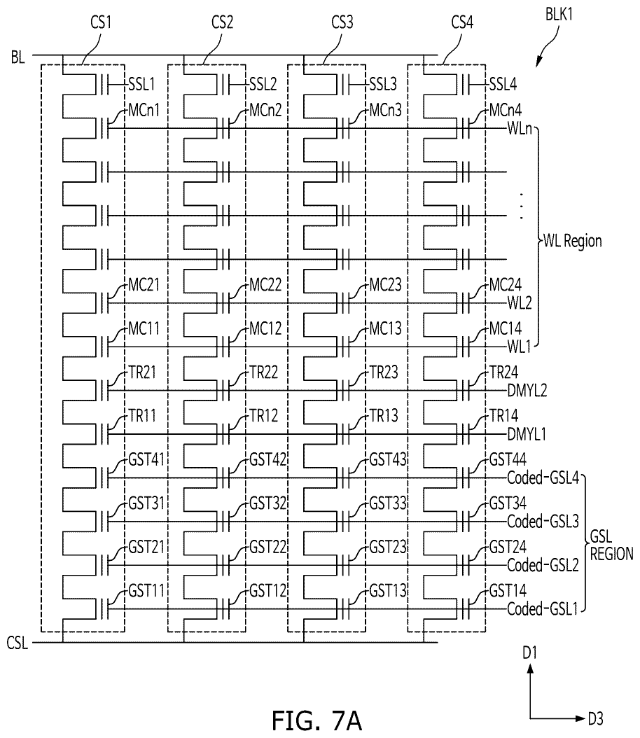

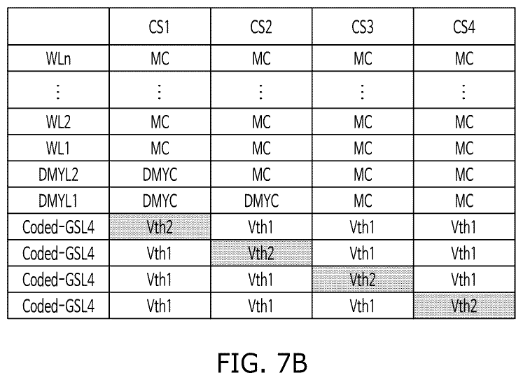

FIG. 7A is a view illustrated to explain the structure of a memory block BLK1 according to embodiments of the present disclosure. The memory block BLK1 of FIG. 7A may correspond to the modification to the memory block BLK1 of FIG. 4A. The redundant description will be omitted.

The memory block BLK1 may further include dummy lines DMYL1 and DMYL2 arranged between a word line region WL Region and a GSL region GSL Region. The dummy lines DMYL1 and DMYL2 may be connected to a plurality of cell strings CS1 to CS4. Specifically, each of the dummy lines DMYL1 and DMYL2 may be connected to transistors TR11 to TR24 arranged between the word line region WL Region and the GSL region GSL Region.

According to an exemplary embodiment, among ground select transistors GST11, GST21, GST31 and GST41 included in the first cell string CS1, the ground select transistor GST41 may be programmed with the second threshold voltage, and among ground select transistors GST12, GST22, GST32 and GST42 included in the second cell string CS2, the ground select transistor GST32 may be programmed with the second threshold voltage. Among ground select transistors GST13, GST23, GST33 and GST43 included in the third cell string CS3, the ground select transistor GST23 may be programmed with the second threshold voltage, and among ground select transistors GST14, GST24, GST34 and GST44 included in the fourth cell string CS4, the ground select transistor GST14 may be programmed with the second threshold voltage. However, the present disclosure is not limited thereto.

In this case, two (2) transistors adjacent to the ground select transistor programmed with the second threshold voltage in the first direction D1, among the transistors connected to the dummy lines DMYL1 and DMYL2, may be used as a dummy cell in which user data is not stored. In addition, the other transistors may be used as memory cells in which user data is stored. For example, the transistors TR11, TR12, and TR21 may be used as dummy cells, and the transistors TR13, TR14, TR22, TR23, and TR24 may be used as memory cells.

According to embodiments, the number of memory cells in which user data is stored included in the cell strings may vary depending on the distances between the locations of the ground select transistors programmed with the second threshold voltage in the first direction D1 and a predetermined line. As the distance between the locations of the ground select transistors programmed with the second threshold voltage in the first direction D1 and the predetermined line increases, the difference between the numbers of memory cells in which user data is stored included, which are in the cell strings may increase.

According to an embodiment where ground select transistors GST41, GST32, and GST23 are programmed with the second threshold voltage, the number of memory cells included in the cell string CS1 may be n, the number of memory cells included in the cell string CS2 may be (n+1), and the number of memory cells included in the cell string CS3 may be (n+2). Since the difference between the distance from the common source line CSL to the location of the ground select transistor GST41 in the first direction D1 and the distance from the common source line CSL to the location of the ground select transistor GST23 in the first direction D1 is greater than the difference between the distance from the common source line CSL to the location of the ground select transistor GST41 in the first direction D1 and the distance from the common source line CSL to the location of the ground select transistor GST32 in the first direction D1, the difference between the number of memory cells included in the first cell string CS1 and the number of memory cells included in the third cell string CS3 may be greater than the difference between the number of memory cells included in the first cell string CS1 and the number of memory cells included in the second cell string CS2.

FIG. 7B is a view illustrated to briefly explain the structure of a memory block of FIG. 7A. The redundant description from FIG. 6B will be omitted.

Referring to FIG. 7B, dummy lines DMYL1 and DMYL2 may be arranged between a plurality of word lines WL1 to WLn (where n is a natural number greater than or equal to two (2)) and a plurality of programmed ground selection lines Coded-GSL1 to Coded-GSL4. Transistors connected to the dummy lines DMYL1 and DMYL2 may be used as dummy cells DMYC in which user data is not stored or memory cells MC in which user data is stored.

According to an embodiment, two (2) transistors arranged on the upper side adjacent to the ground select transistor programmed with the second threshold voltage Vth2 among the transistors connected to the dummy lines DMYL1 and DMYL2 may be used as the dummy cells DMYC in which user data is not stored. However, a ground select transistor may be an exception. Accordingly, two (2) transistors included in the first cell string CS1 and one transistor included in the second cell string CS2 among the transistors connected to the dummy lines DMYL1 and DMYL2 may be used as the dummy cells DMYC, and one transistor included in the second cell string CS2 and the transistors included in third to fourth cell strings CS3 to CS4 may be used as the memory cells MC. However, the present disclosure is not limited thereto.

The number of memory cells in which user data is stored of the cell string may vary depending on the location of the ground select transistor programmed with the second threshold voltage Vth2 in the first direction (e.g., direction D1 of FIG. 7A).

According to embodiments, when a first dummy line DMYL1 is arranged adjacent to the programmed ground selection lines Coded-GSL1 to Coded-GSL4 rather than a second dummy line DMYL2, the number of memory cells MC in which user data is stored, which are connected to the first dummy line DMYL1 may be smaller than the number of memory cells MC in which user data is stored, which are connected to the second dummy line DMYL2.

According to an embodiment of FIG. 7B, two (2) transistors disposed on the upper end adjacent to the ground select transistor programmed with the second threshold voltage Vth2 may be used as the dummy cell DMYC. Therefore, the stability of memory devices may be improved by reducing the effects of degradation.

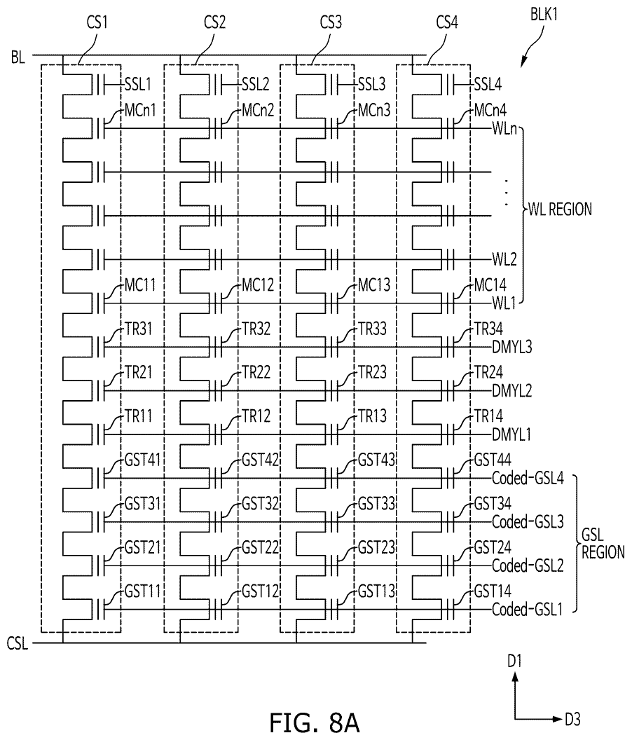

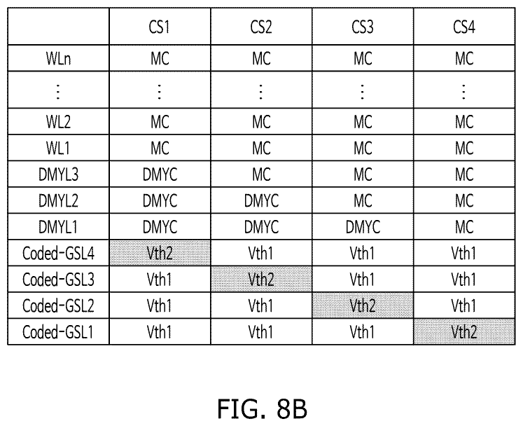

FIG. 8A is a view illustrated to explain the structure of a memory block BLK1 according to the embodiment of the present disclosure. The memory block BLK1 of FIG. 8A may correspond to the modification to the memory block BLK1 of FIG. 4A. The redundant description from FIG. 6A and FIG. 7A will be omitted.

The memory block BLK1 may further include dummy lines DMYL1, DMYL2 and DMYL3 arranged between a word line region WL Region and a GSL region GSL Region. The dummy lines DMYL1, DMYL2 and DMYL3 may be connected to a plurality of cell strings CS1 to CS4. Specifically, each of the dummy lines DMYL1, DMYL2 and DMYL3 may be connected to transistors TR11 to TR34 arranged between the word line region WL Region and the GSL region GSL Region.

According to an exemplary embodiment, among ground select transistors GST11, GST21, GST31 and GST41 included in a first cell string CS1, a ground select transistor GST41 may be programmed with the second threshold voltage, and among ground select transistors GST12, GST22, GST32 and GST42 included in the second cell string CS2, a ground select transistor GST32 may be programmed with the second threshold voltage. Among ground select transistors GST13, GST23, GST33, and GST43 included in a third cell string CS3, a ground select transistor GST23 may be programmed with the second threshold voltage, and among ground select transistors GST14, GST24, GST34, and GST44 included in a fourth cell string CS4, a ground select transistor GST14 may be programmed with the second threshold voltage. However, the present disclosure is not limited thereto.

Three (3) transistors adjacent to the ground select transistor programmed with the second threshold voltage in the first direction D1, among the transistors connected to the dummy lines DMYL1 DMYL2 and DMYL3, may be used as dummy cells in which user data is not stored, and other transistors may be used as memory cells in which user data is stored. For example, transistors TR11, TR12, TR13, TR21, TR22 and TR31 may be used as dummy cells, and transistors TR14, TR23, TR24, TR32, TR33 and TR34 may be used as memory cells.

According to an embodiment where ground select transistors GST41, GST32, GST23 and GST14 are programmed with the second threshold voltage, the number of memory cells included in the cell string CS1 may be n (where n is a natural number greater than or equal to two (2)), the number of memory cells included in the cell string CS2 may be (n+1), the number of memory cells included in the cell string CS3 may be (n+2), and the number of memory cells included in the cell string CS4 may be (n+3). The number of memory cells included in each of the first to fourth cell strings CS1 to CS4 may be different depending on the difference in the distance from the common source line CSL to the location of each of the ground select transistors GST41, GST32, GST23 and GST14 in the first direction D1.

FIG. 8B is a view illustrated to briefly explain the structure of the memory block. The redundant description from FIG. 6B and FIG. 7B will be omitted.

Referring to FIG. 8B, the dummy lines DMYL1, DMYL2, and DMYL3 may be arranged between the plurality of word lines WL1 to WLn and the plurality of programmed ground selection lines Coded-GSL1 to Coded-GSL4. Transistors connected to the dummy lines DMYL1, DMYL2 and DMYL3 may be used as dummy cells DMYC in which user data is not stored or memory cells MC in which user data is stored.

According to embodiments, three (3) transistors arranged on the upper side adjacent to the ground select transistor programmed with the second threshold voltage Vth2 among the transistors connected to the dummy lines DMYL1, DMYL2 and DMYL3 may be used as the dummy cell DMYC in which user data is not stored. However, a ground select transistor may be an exception. Accordingly, among the transistors connected to the dummy lines DMYL1, DMYL2 and DMYL3, three (3) transistors included in the first cell string CS1, two (2) transistors included in the second cell string CS2, and one (1) transistor included in the third cell string CS3 may be used as the dummy cells DMYC, and one (1) transistor included in the second cell string CS2, two (2) transistors included in the third cell string CS3, and three (3) transistors included in the fourth cell string CS4 may be used as the memory cells MC. However, the present disclosure is not limited thereto.

The number of memory cells in which user data is stored of the cell string may vary depending on the location of the ground select transistor programmed with the second threshold voltage Vth2 in the first direction (e.g., direction D1 of FIG. 8A).

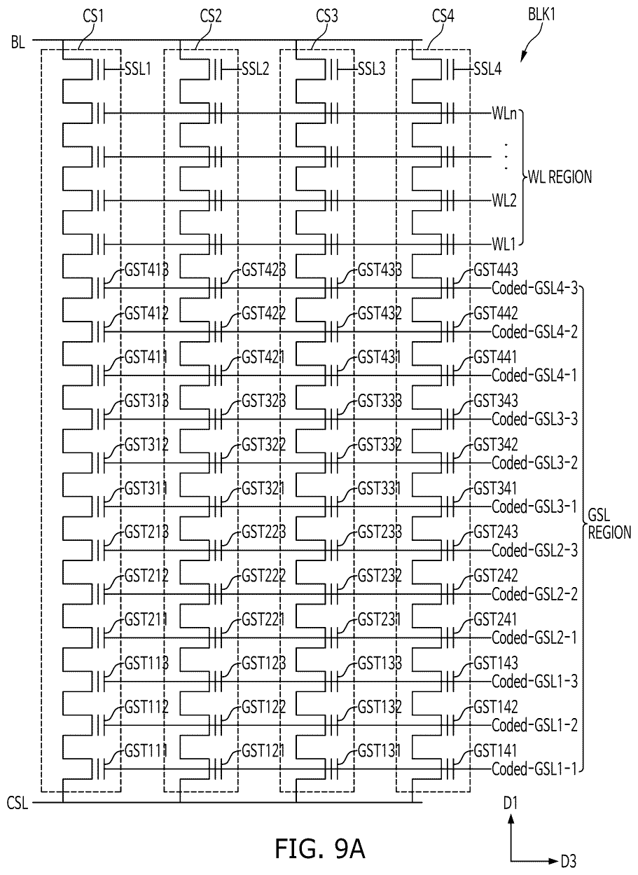

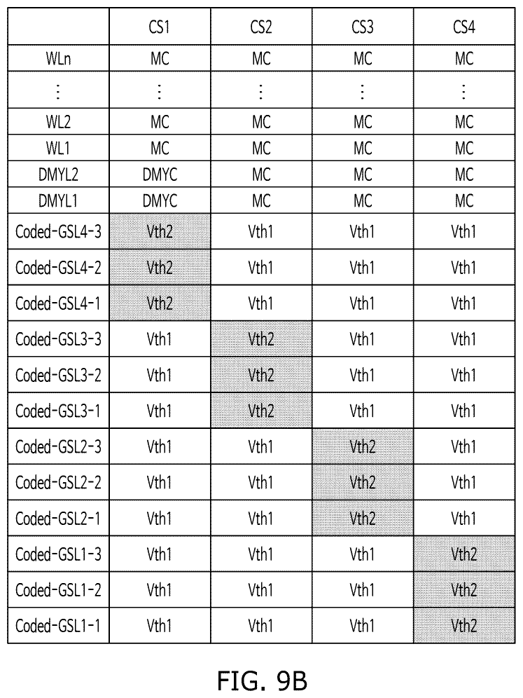

FIG. 9A is a view illustrated to explain the structure of a memory block BLK1 according to embodiments. The memory block BLK1 of FIG. 9A may correspond to the modification of the memory block BLK1 of FIG. 4A. The redundant description from FIG. 4A will be omitted.

According to embodiments, each of first, second, third, and fourth programmed ground selection lines may be arranged in multiples. Referring to FIG. 9A, each of the first to fourth programmed ground selection lines may include three (3) programmed sub-ground selection lines. For example, the first programmed ground selection line may include first-1st to first-3rd programmed sub-ground selection lines Coded-GSL1-1 to Coded-GSL1-3, the second programmed ground selection line may include second-1st to second-3rd programmed sub-ground selection lines Coded-GSL2-1 to Coded-GSL2-3, the third programmed ground selection line may include third-1st to third-3rd programmed sub-ground selection lines Coded-GSL3-1 to Coded-GSL3-3, and the fourth programmed ground selection line may include fourth-1st to fourth-3rd programmed sub-ground selection lines Coded-GSL4-1 to Coded-GSL4-3.

The same voltage may be applied to each of the three (3) programmed sub-ground selection lines, and the ground select transistors respectively connected to the three (3) programmed sub-ground selection lines may be programmed with the same threshold voltage. Accordingly, even though the electrical isolation characteristic of any one of the three (3) sub-ground selection lines is reduced, the electrical isolation characteristic of other lines may be maintained.

FIG. 9A illustrates an example where each of first to fourth programmed ground selection lines includes three (3) programmed sub-ground lines. However, the present disclosure is not limited thereto. Therefore, each of the first to fourth programmed ground selection lines may include various numbers of the sub-ground selection lines.

FIG. 9B is a view illustrated to briefly explain the structure of the memory block of FIG. 9A. The redundant description from FIG. 6B, FIG. 7B and FIG. 8B will be omitted. FIG. 9B illustrates an example in which two (2) dummy lines DMYL1 and DMYL2 are added to a memory block BLK1 of FIG. 9A.

Referring to FIG. 9B, the dummy lines DMYL1 and DMYL2 may be arranged between the plurality of word lines WL1 to WLn and a plurality of programmed sub-ground selection lines Coded-GSL1-1 to Coded-GSL4-3. Transistors connected to the dummy lines DMYL1 and DMYL2 may be used as the dummy cells DMYC in which user data is not stored or the memory cells MC in which user data is stored.

According to embodiments, when the memory block includes a plurality of programmed sub-ground selection lines, the number of memory cells in which the user data is stored of the cell string may vary depending on the location of a ground select transistor disposed on the upper end in the first direction D1 among the ground select transistors programmed with the second threshold voltage Vth2 of the cell string. When the memory block includes a plurality of programmed sub-ground selection lines, the number of memory cells in which user data is stored of the cell string may vary depending on the location of the ground select transistor farthest from a predetermined line in the first direction D1, among the ground select transistors programmed with the second threshold voltage Vth2 of the cell string. The predetermined line may be the common source line CSL, but the present disclosure is not limited thereto.

For example, two (2) transistors disposed on the upper end adjacent to the ground select transistor farthest from the predetermined line among the ground select transistors programmed with the second threshold voltage Vth2 included in each cell string may be used as the dummy cell DMYC in which the user data is not stored. However, a ground select transistor may be an exception. Therefore, two (2) transistors included in the first cell string CS1, among the transistors connected to the dummy lines DMYL1 and DMYL2, may be used as the dummy cell DMYC, and other transistors connected to the dummy lines DMYL1 and DMYL2 may be used as the memory cell MC. However, the present disclosure is not limited thereto.

FIG. 9B illustrates that the ground select transistors programmed with the second threshold voltage Vth2 included in the same cell string are placed adjacent to each other, but the present disclosure is not limited thereto. For example, the ground select transistors programmed with the second threshold voltage Vth2 included in the same cell string may be disposed spaced apart from each other in the GSL region.

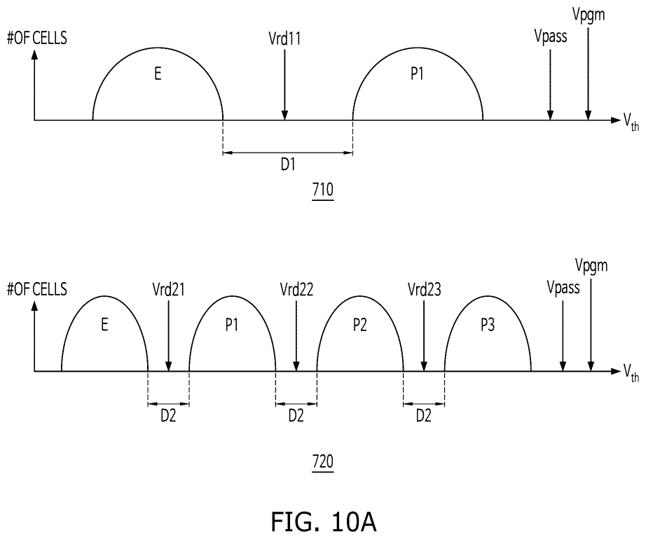

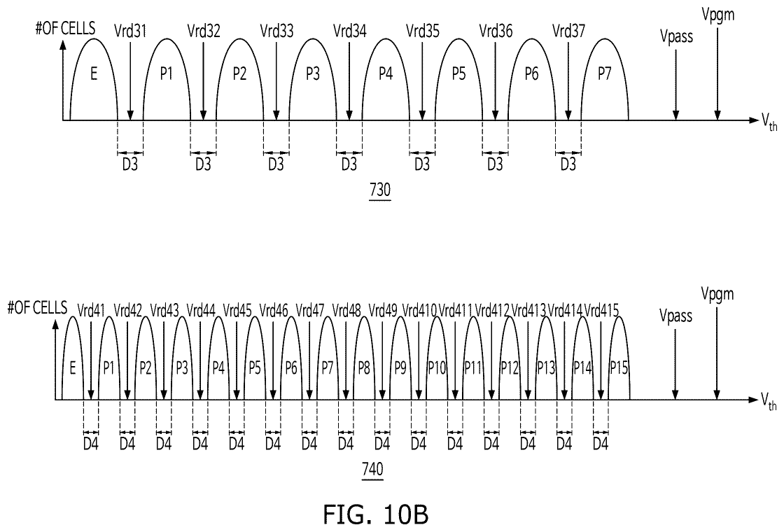

FIG. 10A and FIG. 10B are views illustrated to explain states of memory cells according to embodiments of the present disclosure.

FIGS. 10A and 10B illustrate a graph 710 for states E and P1 of an SLC, a graph 720 for states E and P1 to P3 of an MLC, a graph 730 for states E and P1 to P7 of a TLC, and a graph 740 for states E and P1 to P15 of a QLC.

In graphs 710, 720, 730, and 740 of FIG. 10A and FIG. 10B, the horizontal axis indicates a threshold voltage Vth of the memory cell, and the vertical axis indicates the number of memory cells corresponding to the threshold voltage Vth or a memory cell count value.

A plurality of memory cells may include a plurality of threshold voltage level distributions according to programmed data. When a memory cell is an SLC that stores one (1) bit for each memory cell, the memory cells may have two (2) threshold voltage distributions according to program states. For another example, when a memory cell is an MLC that stores two (2) bits for each memory cell, the memory cells may have four (4) threshold voltages according to program states. For another example, when a memory cell is a TLC that stores three (3) bits for each memory cell, the memory cells may have eight (8) threshold voltages according to the program states of the memory cells. In the similar manner, when the memory cell is a QLC that stores four (4) or more bits for each memory cell, the memory cells may have sixteen or more threshold voltage distributions according to the program states of the memory cells. One threshold voltage distribution may correspond to a specific state of the memory cell.

During the program operation, after a pass voltage Vpass is applied to all the word lines, and a program voltage Vpgm may be applied to a selected word line. The pass voltage Vpass may be a voltage enough to turn on the memory cell. For example, the pass voltage Vpass may be a program pass voltage during the program operation. The program voltage Vpgm may be greater than the pass voltage Vpass.

During the read operation, the state of each memory cell may be identified by applying a read voltage Vrd to a selected word line, and the pass voltage Vpass to a non-selected word line.

The distances between the threshold voltage distributions may vary depending on the number of bits that one memory cell is capable of storing. For example, referring to graph 710 and graph 720, a distance D1 between threshold voltage distributions of the memory cell, which is the SLC, may be greater than a distance D2 between the threshold voltage distributions of the memory cell, which is the MLC. In addition, referring to graph 720 and graph 730, the distance D2 between the threshold voltage distributions of the memory cell, which is the MLC may be greater than a distance D3 between the threshold voltage distributions of the memory cell, which is the TLC. Referring to graph 730 and graph 740, a distance D3 between the threshold voltage distributions of the memory cell, which is the TLC may be greater than a distance D4 between the threshold voltage distributions of the memory cell, which is a QLC. Therefore, a relatively stable performance may be maintained even through degradation proceeds because the memory cell, which is the SLC, has a greater distance between the threshold voltage distributions than that of the memory cell, which is the MLC memory. In addition, a relatively stable performance may be maintained even through degradation proceeds because the memory cell, which is the MLC, has a greater distance between the threshold voltage distributions than that of the memory cell, which is the TLC. A relatively stable performance may be maintained even through degradation proceeds because the memory cell, which is the TLC memory, has a greater distance between the threshold voltage distributions than that of the memory cell, which is the QLC.

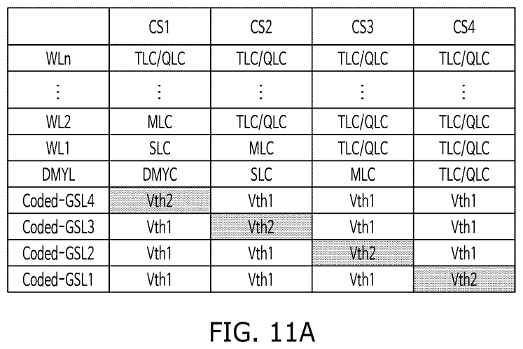

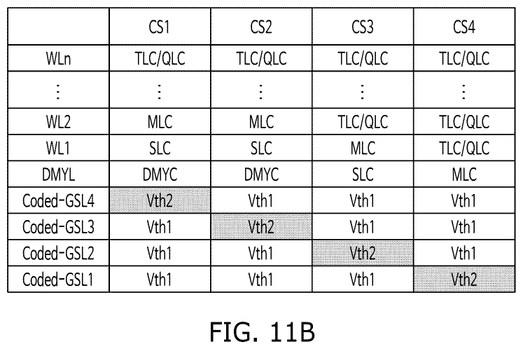

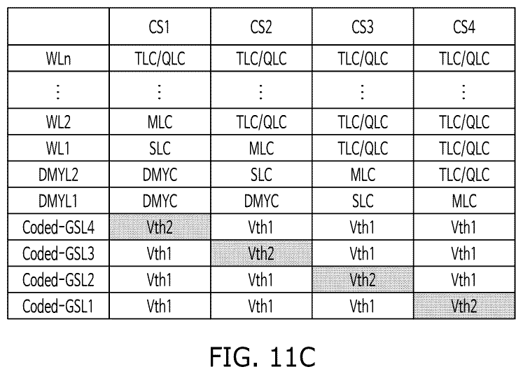

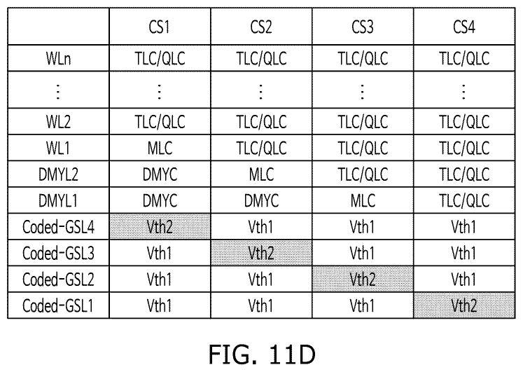

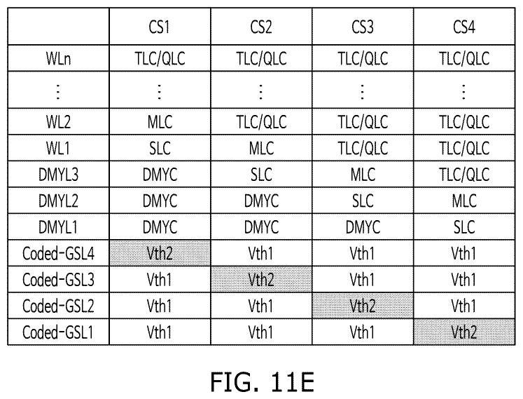

FIG. 11A, FIG. 11B, FIG. 11C, FIG. 11D, and FIG. 11E are views illustrated to explain the structure of a memory block according to embodiments. The redundant description will be omitted.

According to embodiments, the number of bits of data stored in a plurality of memory cells connected to one word line or one dummy line may vary depending on the location of the ground select transistors programmed with the second threshold voltage Vth2 in a first direction (e.g., direction D1 of FIG. 6A). However, the present disclosure is not limited thereto, but may include a memory cell that stores data in the same number of bits among the plurality of memory cells connected to the one word line or the one dummy line.

According to embodiments, when a first memory cell and a second memory cell are connected to one word line or one dummy line, the number of bits of data stored in the first memory cell, and the number of bits of data stored in the second memory cell may vary depending on a first location in the first direction of the ground select transistor programmed with the second threshold voltage Vth2 in a first cell string including a first memory cell, and a second location in the first direction of the ground select transistor programmed with the second threshold voltage Vth2 in a second cell string including the second memory cell. When a first distance between a predetermined line and a first location is smaller than a second distance between a predetermined line and a second location, the number of bits of data stored in the first memory cell may be greater than the number of bits of data stored in the second memory cell. The predetermined line may be the common source line (CSL, not shown), but the present disclosure is not limited thereto. The predetermined line may be an arbitrary line extending in the third direction (e.g., direction D3 of FIG. 4A) and disposed on the bottom of the GSL region.

According to embodiments, as the difference between the first distance and the second distance increases, the difference between the number of bits of data stored in the first memory cell, and the number of bits of data stored in the second memory cell may increase.

According to embodiments, a cell string may include a third memory cell and a fourth memory cell in which user data is stored. The memory cells included in one cell string may be disposed along the first direction. The number of bits of data stored in the third memory cell may be different from the number of bits of data stored in the fourth memory cell depending on a third location in the first direction of a third memory cell and a fourth location in the first direction of a fourth memory cell. When a third distance between a predetermined line and the third location is smaller than a fourth distance between the predetermined line and a fourth location, the number of bits of data stored in the third memory cell may be smaller than the number of bits of data stored in the fourth memory cell.

FIG. 11A, FIG. 11B, FIG. 11C, FIG. 11D, and FIG. 11E illustrate the structure of the memory block according to embodiments of the present disclosure.

FIG. 11A illustrates an embodiment where a dummy line DMYL is placed between a plurality of word lines WL1 to WLn (where n is a natural number greater than or equal to two (2)) and a plurality of programmed ground selection lines Coded-GSL1 to Coded-GSL4.

According to embodiments, the transistor disposed at the upper end adjacent to the first to the ground select transistor programmed with the second threshold voltage Vth2 among the transistors connected to the dummy line DMYC may be used as the dummy cell DMYC in which user data is not stored. The transistor disposed at the upper end adjacent second to the ground select transistor programmed with the second threshold voltage Vth2 may be the SLC that stored the data of one bit. the transistor disposed at the upper end adjacent to the first to the ground select transistor programmed with the second threshold voltage Vth2 among the transistors connected to the dummy line DMYC may be used as the dummy cell DMYC in which user data is not stored. The transistor disposed at the top adjacent second to the ground select transistor programmed with the second threshold voltage Vth2 may be the SLC that stores the data of one bit.

FIG. 11B illustrates an embodiment in which the dummy line DMYL is placed between the plurality of word lines WL1 to WLn (where n is a natural number greater than or equal to two (2)) and the plurality of programmed ground selection lines Coded-GSL1 to Coded-GSL4.

According to embodiments, a transistor placed at the upper side which is first adjacent to the ground select transistor programmed with the second threshold voltage Vth2, among the transistors connected to the dummy line DMYC, may be used as the dummy cell DMYC. In addition, a transistor placed at the upper side second adjacent to the ground select transistor programmed with the second threshold voltage Vth2 may be either the dummy cell DMYC or the SLC. A transistor arranged at the upper side third adjacent to the ground select transistor programmed with the second threshold voltage Vth2 may be either SLC or MLC. A transistor arranged at the upper side that is fourth adjacent to the ground select transistor programmed with the second threshold voltage Vth2 may be either MLC, TLC or QLC. In addition, the other memory cells may be either TLC or QLC. However, the transistor connected to the programmed ground selection line may be excluded.

FIG. 11C illustrates an embodiment in which the dummy lines DMYL1 and DMYL2 are arranged between the plurality of word lines WL1 to WLn (where n is a natural number greater than or equal to two (2)) and the plurality of programmed ground selection lines Coded-GSL1 to Coded-GSL4.

According to embodiments, a transistor arranged at the upper side that is first adjacent to the ground select transistor programmed with the second threshold voltage Vth2, among the transistors connected to the dummy lines DMYL1 and DMYL2, may be used as the dummy cell DMYC. A transistor arranged at the upper side that is second adjacent to the ground select transistor programmed with the second threshold voltage Vth2 may be used as the dummy cell DMYC. A transistor arranged at the upper side that is third adjacent to the ground select transistor programmed with the second threshold voltage Vth2 may be SLC. A transistor arranged at the upper side that is fourth adjacent to the ground select transistor programmed with the second threshold voltage Vth2 may be MLC. In addition, the other memory cells may be either TLC or QLC. However, the transistor connected to the programmed ground selection line may be excluded.

FIG. 11D illustrates an embodiment in which the dummy lines DMYL1 and DMYL2 are arranged between the plurality of word lines WL1 to WLn (where n is a natural number greater than or equal to two (2)) and the plurality of programmed ground selection lines Coded-GSL1 to Coded-GSL4.

According to embodiments, among the transistors connected to the dummy lines DMYL1 and DMYL2, a transistor arranged at the upper side that is first adjacent to the ground select transistor programmed with the second threshold voltage Vth2 may be used as the dummy cell DMYC. A transistor arranged at the upper side that is second adjacent to the ground select transistor programmed with the second threshold voltage Vth2 may be used as the dummy cell DMYC. A transistor arranged at the upper side that is third adjacent to the ground select transistor programmed with the second threshold voltage Vth2 may be MLC. A transistor arranged at the upper side that is fourth or more adjacent to the ground select transistor programmed with the second threshold voltage Vth2 may be either TLC or QLC. However, the transistor connected to the programmed ground selection line may be excluded.

FIG. 11E illustrates an embodiment in which dummy lines DMYL1, DMYL2 and DMYL3 are arranged between the plurality of word lines WL1 to WLn (where n is a natural number greater than or equal to two (2)) and the plurality of programmed ground selection lines Coded-GSL1 to Coded-GSL4.

According to embodiments, among the transistors connected to the dummy lines DMYL1, DMYL2 and DMYL3, a transistor arranged at the upper side that is first adjacent to the ground select transistor programmed with the second threshold voltage Vth2 may be used as the dummy cell DMYC. A transistor arranged at the upper side that is second adjacent to the ground select transistor programmed with the second threshold voltage Vth2 may be used as the dummy cell DMYC. In addition, a transistor arranged at the upper side that is third adjacent to the ground select transistor programmed with the second threshold voltage Vth2 may be used as the dummy cell DMYC. In addition, a transistor arranged at the upper side fourth adjacent to the ground select transistor programmed with the second threshold voltage Vth2 may be the SLC. A transistor arranged on the upper side fifth adjacent to the ground select transistor programmed with the second threshold voltage Vth2 may be the MLC. In addition, the other memory cells may be either the TLC or the QLC. However, the transistor connected to the programmed ground selection line may be excluded.

According to embodiments, a dummy cell in which user data is not stored may be used as a transistor adjacent to the ground select transistor programmed with the second threshold voltage Vth2 in the first direction, or a memory cell that maintains a relatively stable performance may be used even though a degradation proceeds due to the distance between the threshold voltage distributions. Therefore, the performance of the Coded GSL structure may be stably maintained and the memory cells included in the memory device may be effectively used. Therefore, the integration of the memory device may be improved.

According to embodiments, the number of bits of data stored in the plurality of memory cells connected to one word line or one dummy line may vary depending on the locations of the ground select transistors programmed with the second threshold voltage Vths (e.g., direction D1 of FIG. 6A). However, the present disclosure is not limited thereto, but may include a memory cell that stores the number of bits of data among the plurality of memory cells connected to one word line or one dummy line.

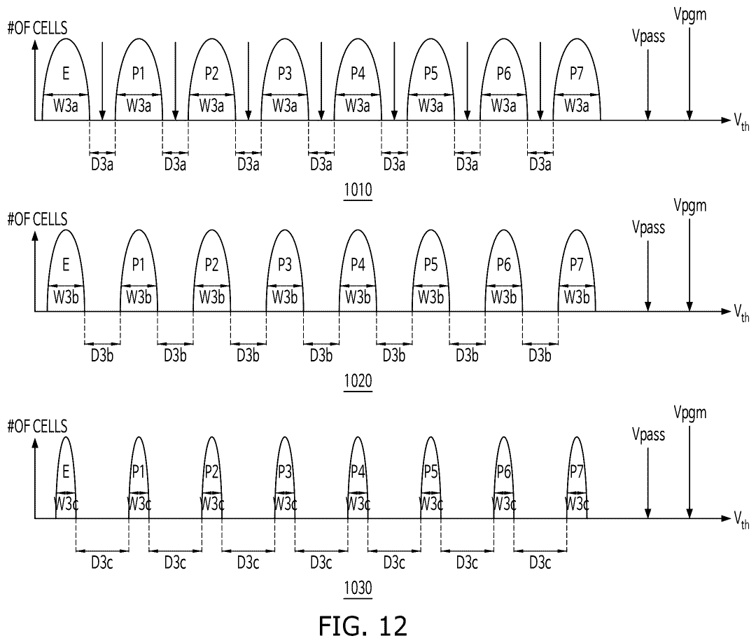

FIG. 12 is a view illustrated to explain states of memory cells according to embodiments of the present disclosure.

FIG. 12 illustrates states E and P1 to P7 of TLC forming various threshold voltage distributions. In FIG. 12, the horizontal axis may indicate the threshold voltage Vth of a memory cell, and the vertical axis may indicate the number of memory cells (#of cells) or the memory cell count value corresponding to the threshold voltage Vth. Although the embodiment in FIG. 12 is illustrated based on TLC, the embodiments of the present disclosure are not limited thereto, and the embodiments of the present disclosure described below may also be applied to SLC, MLC, QLC, etc.

For convenience of explanation, a memory cell corresponding to graph 1010 may be referred to as a first memory cell, a memory cell corresponding to graph 1020 may be referred to as a second memory cell, and a memory cell corresponding to graph 1030 may be referred to as a third memory cell.

Among the plurality of memory cells, various widths of threshold voltage distributions may be formed according to various elements, and the width of the threshold distribution may be formed to be constant in the same memory cell. For example, the program operation on the plurality of memory cells, may be performed by an Incremental Step Pulse Programming (ISPP) method that increases a program voltage by unit of step voltage. When the width of the step voltage is set to be narrow in ISPP, it is possible to precisely reach a target voltage during the program operation to narrow the threshold voltage distribution of the memory cell.

Referring to FIG. 12, a width W3a of the threshold voltage distribution of the first memory cell may be greater than a width W3b of the threshold voltage distribution of the second memory cell. Therefore, a distance D3a between the threshold voltage distributions of the first memory cell may be smaller than a distance D3b between the threshold voltage distributions of the second memory cell may be smaller than a distance D3c between the threshold voltage distributions of the third memory cell. Therefore, even though the degradation proceeds in the order of the third memory cell, the second memory cell, and the first memory cell, the relatively stable performance may be maintained.

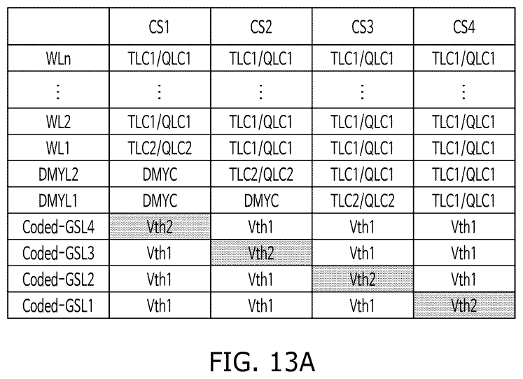

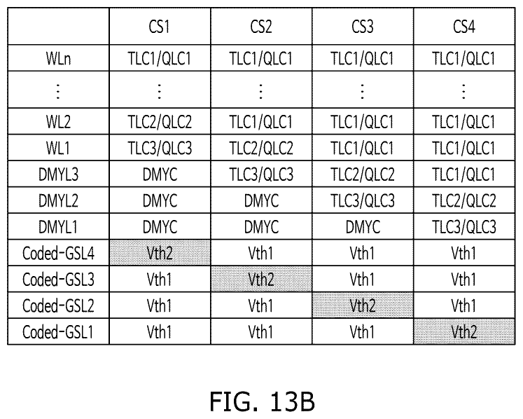

FIG. 13A and FIG. 13B are views illustrated to explain the structure of a memory block according to various embodiments of the present disclosure. The redundant description will be omitted. In FIG. 13A and FIG. 13B, TLCn or QLCn (where n is a natural number) may be an expression that relatively compares the width of the threshold voltage distribution of TLC or QLC memory cell. N may be an order in which the width of the threshold voltage narrows, and as the value of n increases, the threshold voltage distribution width may narrow. For example, among the memory cells from TLC1 to TLC3, TLC3 may have the narrowest threshold voltage distribution width, and TLC1 may have the widest threshold voltage distribution width.

According to embodiments, the cell string may include a fifth memory cell and a sixth memory cell in which user data is stored. The memory cells included in one cell string may be arranged along the first direction (e.g., direction D1 of FIG. 4A). A width of the threshold voltage distribution of the fifth memory cell may be different from a width of the threshold voltage distribution of the sixth memory cell according to a fifth location of a fifth memory cell in the first direction, and a sixth location of a sixth memory cell in the first direction. When a fifth distance between a predetermined line to the fifth location is shorter than a sixth distance between the predetermined line and the sixth location, the fifth memory cell may be programmed to form a first threshold voltage distribution, and the sixth memory cell may be programmed to form a second threshold voltage distribution having a greater width than the first threshold voltage distribution.

FIG. 13A illustrates an embodiment in which dummy lines DMYL1 and DMYL2 are placed between a plurality of word lines WL1 to WLn and a plurality of programmed ground selection lines Coded-GSL1 to Coded-GSL4.

According to embodiments, among the transistors connected to the dummy lines DMYL1 and DMYL2, a transistor arranged at the upper side that is first adjacent to the ground select transistor programmed with the second threshold voltage Vth2 may be used as a dummy cell DMYC. A transistor arranged at the upper side that is second adjacent to the ground select transistor programmed with the second threshold voltage Vth2 may be used as the dummy cell DMYC. A transistor arranged at the upper side that is third adjacent to the ground select transistor programmed with the second threshold voltage Vth2 may be either a TLC2 or a QLC2. In addition, a transistor arranged at the upper side that is fourth or more adjacent to the ground select transistor programmed with the second threshold voltage Vth2 may be either a TLC1 or a QLC1. However, the transistor connected to the programmed ground selection line may be excluded.

FIG. 13B illustrates an embodiment in which dummy lines DMYL1, DMYL2 and DMYL3 are placed between the plurality of word lines WL1 to WLn and the plurality of programmed ground selection lines Coded-GSL1 to Coded-GSL4.

According to embodiments, among the transistors connected to the dummy lines DMYL1, DMYL2 and DMYL3, a transistor arranged at the upper side that is first adjacent to the ground select transistor programmed with the second threshold voltage Vth2may be used as the dummy cell DMYC. A transistor arranged at the upper side that is second adjacent to the ground select transistor programmed with the second threshold voltage Vth2 may be used as the dummy cell DMYC. A transistor arranged at the upper side that is third adjacent to the ground select transistor programmed with the second threshold voltage Vth2 may be used as the dummy cell DMYC. A transistor arranged on the upper side fourth adjacent to the ground select transistor programmed with the second threshold voltage Vth2 may be either a TLC3 or a QLC3. A transistor arranged on the upper side fifth adjacent to the ground select transistor programmed with the second threshold voltage Vth2 may be either a TLC2 or a QLC2. In addition, the other memory cells may be either a TLC1 or a QLC1. However, the transistor connected to the programmed ground selection line may be excluded.

According to embodiments, a transistor adjacent to a ground select transistor programmed with the second threshold voltage Vth2 in the first direction may be used as the dummy cell in which user data is not stored, or a memory cell that maintains relatively stable performance even through degradation proceeds because a width of the threshold voltage distribution is programmed to be narrow. Therefore, the performance of the Coded GSL structure may be stably maintained and the memory cells included in the memory device may be effectively used. Accordingly, the integration of the memory system including the memory device may be improved.

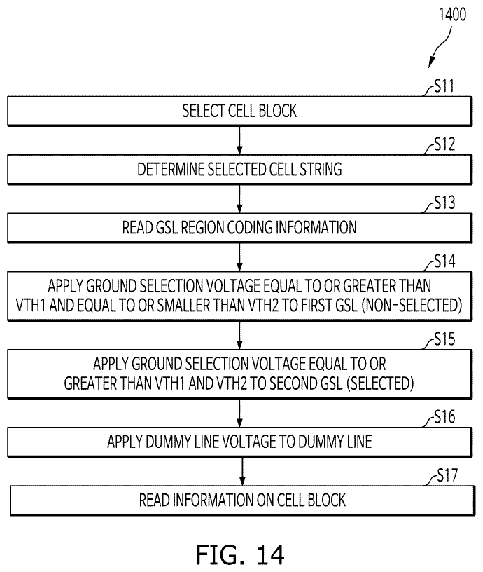

FIG. 14 is a flowchart illustrating an operation method 1400 of a memory device according to embodiments of the present disclosure. The operation method 1400 of FIG. 14 may be performed by a control logic (e.g., the control logic 124 of FIG. 1).

During the manufacturing process of the memory device, coding on the GSL region according to embodiments may be performed, and GSL region coding information may be stored in a storage circuit that stores information in the memory device in a non-volatile manner. For example, the GSL region coding information may be stored in the control logic circuit in the memory device. The GSL region coding information may include information on the threshold voltages associated with various lines provided in the GSL region or information on the voltages provided to various lines according to the selected cell string.

Referring to FIG. 14, the control logic may select at least one memory cell block among the plurality of memory cells included in the memory cell array in step S11. The control logic may select a cell block to perform at least one of a program operation, a read operation, or an erase operation based on the control signal received from the memory controller. The control logic may identify the cell string selected among the plurality of cell strings connected to the same bit line in the selected memory cell block in step S12. The control logic may read the GSL region coding information stored in the memory device in the non-volatile manner for performing the program, read, or erase operation in step S13. Voltage levels applied to various lines connected to the memory cell block selected based on the read GSL region coding information may be adjusted.

According to an exemplary embodiment, when a selected cell string is connected to first and second programmed ground selection lines, and a ground select transistor connected to a first programmed ground selection line is programmed with a first threshold voltage Vth1, the control logic may apply a ground selection voltage having a level higher than the first threshold voltage Vth1 and lower than the second threshold voltage Vth2 to the first programmed ground selection line in step S14. In addition, when the ground select transistor connected to a second programmed ground selection line is programmed with the second threshold voltage Vth2, the control logic may apply a ground selection voltage having a level higher than the first threshold voltage Vth1 and the second threshold voltage Vth2 to the second programmed ground selection line in step S15. In addition, the control logic may apply a dummy line voltage to a dummy line in step S16. For example, when dummy cells connected to the dummy line are programmed with a voltage of at a level corresponding to the average of the first threshold voltage Vth1 and the second threshold voltage Vth2, the control logic may apply a dummy line voltage having a level equal to or higher than (Vth1+Vth2)/2 to the dummy line. Based on the voltage applied to various lines in the GSL region as described above, the control logic may read information on the selected cell block in step S17.

The flowchart and the description thereof with respect to FIG. 14 are only exemplary, but may be differently embodied in other embodiments. For example, according to other embodiments, the order of steps may be changed, a part of steps is repeatedly performed, omitted, or added.

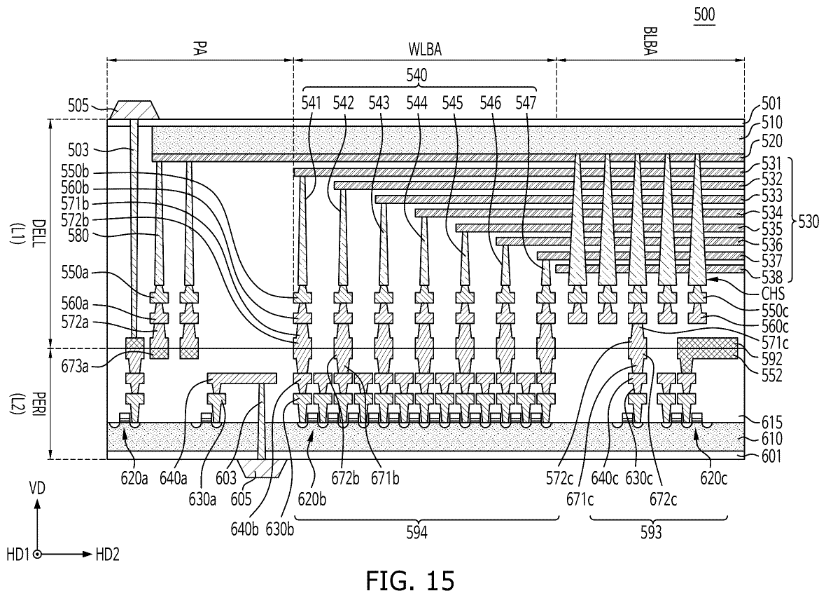

FIG. 15 is a cross-sectional view illustrating a memory device 500 having a B-VNAND structure according to embodiments of the present disclosure.

Referring to FIG. 15, a cell region CELL of a memory device 500 may correspond to a first semiconductor layer L1, and a peripheral circuit region PERI may correspond to a second semiconductor layer L2. Each of the peripheral circuit region PERI and the cell region CELL of the memory device 500 may include an external pad bonding region PA, a word line bonding region WLBA, and a bit line bonding region BLBA. For example, the plurality of word lines WL, the plurality of string selection lines SSL, the plurality of ground selection lines GSL, and the memory cell array 123 of FIG. 2 may be formed in the first semiconductor layer L1, and the control logic 124, the page buffer 125, the voltage generator 121, and the row decoder 122 may be formed in the second semiconductor layer L2.

The peripheral circuit region PERI may include a first substrate 610, an interlayer insulating layer 615, a plurality of circuit elements 620a, 620b and 620c formed on the first substrate 610, first metal layers 630a, 630b and 630c connected to a plurality of circuit elements 620a, 620b and 620c, respectively, and second metal layers 640a, 640b and 640c formed on the first metal layers 630a, 630b and 630c. According to an exemplary embodiment, the first metal layers 630a, 630b and 630c may be formed of tungsten having a relatively high resistance, and the second metal layers 640a, 640b, and 640c may be formed of copper having a relatively low resistance.

This specification illustrates only the first metal layers 630a, 630b and 630c and the second metal layers 640a, 640b and 640c are illustrated, but the present disclosure is not limited thereto, and at least one more metal layers may be formed on the second metal layers 640a, 640b, and 640c. At least a part of the one or more metal layers formed on the second metal layers 640a, 640b and 640c may be formed of aluminum, etc, which may have a lower resistance than copper forming the second metal layers 640a, 640b and 640c.

The interlayer insulating layer 615 may be disposed on the first substrate 610 to cover a plurality of circuit elements 620a, 620b and 620c, first metal layers 630a, 630b, and 630c, and second metal layers 640a, 640b and 640c, and may include an insulating material such as silicon oxide, silicon nitride, or etc. Lower bonding metals 671b and 672b may be formed on a second metal layer 640b of a word line bonding area WLBA. In the word line bonding area WLBA, the lower bonding metals 671b and 672b of the peripheral circuit region PERI may be electrically connected to upper bonding metals 571b and 572b of the cell region CELL by a bonding method, and the lower bonding metals 671b and 672b and the upper bonding metals 571b and 572b may be formed of aluminum, copper, or tungsten.

The cell region CELL may provide at least one memory block. The cell region CELL may include a second substrate 510 and a common source line 520. On the second substrate 510, a plurality of word lines 530 (531 to 538) may be stacked along a vertical direction VD perpendicular to the upper side of the second substrate 510. String selection lines and ground selection lines may be disposed on the top and the bottom of the word lines 530, and the plurality of word lines 530 may be disposed between the string selection lines and the ground selection line.

In the bit line bonding region BLBA, a channel structure CHS may extend in the direction perpendicular to the upper side of the second substrate 510 to penetrate the word lines 530, the string selection lines, and the ground selection lines. The channel structure CHS may include a data storage layer, a channel layer, and a buried insulating layer, and the channel layer may be electrically connected to a first metal layer 550c and a second metal layer 560c. For example, the first metal layer 550c may be a bit line contact, and the second metal layer 560c may be a bit line. According to an exemplary embodiment, the bit line may extend in a second horizontal direction HD2 parallel to the upper surface of the second substrate 510.

According to an exemplary embodiment, an area where the channel structure CHS and the bit line 560c are arranged may be defined as the bit line bonding area BLBA. The bit line 560c may be electrically connected to the circuit elements 620c that provide a page buffer 593 of the peripheral circuit region PERI in the bit line bonding area BLBA. For example, the bit line 560c may be connected to upper bonding metals 571c and 572c of the cell region CELL, and the upper bonding metals 571c and 572c may be connected to lower bonding metals 671c and 672c connected to the circuit elements 620c of the page buffer 593. Accordingly, the page buffer 593 may be connected to the bit line 560c through bonding metals 571c, 572c, 671c and 672c.

According to embodiments, a memory device 500 may further include a through electrode THV disposed in the bit line bonding area BLBA. The through electrode THV may extend in the vertical direction VD through the word lines 530. The through electrode THV may be connected to the common source line 520 and/or the second substrate 510. Although not shown, an insulating ring may be disposed around the through electrode THV, and the through electrode THV may be insulated from the word lines 530. The through electrode THV may be connected to the peripheral circuit region PERI through the upper bonding metal 572c and the lower bonding metal 672c.

In the word line bonding area WLBA, the word lines 530 may extend along a first horizontal direction HD2 parallel to the top surface of the second substrate 510 and may be connected to a plurality of cell contact plugs 540 (541 to 547). The word lines 530 and the cell contact plugs 540 may be connected to each other at pads in which at least part of the word lines 530 are provided at different lengths along the vertical direction VD. A first metal layer 550b and a second metal layer 560b may be sequentially connected to at the upper portions of the cell contact plugs 540 connected to the word lines 530. The cell contact plugs 540 may be connected to the peripheral circuit region PERI through the upper bonding metals 571b and 572b of the cell region CELL in the word line bonding area WLBA and the lower bonding metals 671b and 672b of the peripheral circuit region PERI.

The cell contact plugs 540 may be electrically connected to circuit elements 620b which provide a row decoder 594 in the peripheral circuit region PERI. According to an exemplary embodiment, the operation voltage of the circuit element 620b which provides the row decoder 594 may be different from the operation voltage of a circuit element 620c which provides a page buffer 593. For example, the operation voltages of the circuit elements 620c that provide the page buffer 593 may be greater than the operation voltages of the circuit elements 620v that provide the row decoder 594.

A common source line contact plug 580 may be arranged in the external pad bonding area PA. The common source line contact plug 580 may be formed of a metal, a metal compound, or a conductive material such as polysilicon, and electrically connected to the common source line 520. A first metal layer 550a and a second metal layer 560a may be sequentially stacked on the common source line contact plug 580. For example, an area where the common source line contact plug 580, the first metal layer 550a, and the second metal layer 560a are arranged may be defined as the external pad bonding area PA.

Input and output pads 505 and 605 may be arranged in the external pad bonding area PA. A lower insulating film 601 covering a lower surface of a first substrate 610 may be formed under the first substrate 610, and first input and output pad 605 may be formed on the lower insulating film 601. The first input and output pad 605 may be connected to at least one of a plurality of circuit elements 620a, 620b and 620c arranged in the peripheral circuit region PERI through a first input and output contact plug 603, and may be separated from the first substrate 610 by the lower insulating film 601. Additionally, a side surface insulating film may be arranged between the first input and output contact plug 603 and the first substrate 610 to electrically isolate the first input and output contact plug 603 from the first substrate 610.

An upper insulating film 501 covering the upper surface of a second substrate 510 may be formed on the upper portion of the second substrate 510, and a second input and output pad 505 may be arranged on the upper insulating film 501. The second input and output pad 505 may be connected to at least one of the plurality of circuit elements 620a, 620b, and 620c arranged in the peripheral circuit region PERI through the second input and output contact plug 503.

According to embodiments, the second substrate 510 and the common source line 520 may not be placed in an area in which the second input and output contact plug 503 are arranged. The second input and output pad 505 may not overlap the word lines 530 in a vertical direction V3. The second input and output contact plug 503 may be separated from the second substrate 510 in the direction parallel to the upper surface of the second substrate 510, and penetrate an interlayer insulating layer of the cell region CELL to be connected to the second input and output pad 505.

According to embodiments, the first input and output pad 605 and the second input and output pad 505 may be selectively formed. For example, the memory device 500 may include only the first input and output pad 605 placed on the upper portion of the first substrate 610, or only the second input and output pad 505 placed on the upper portion of the second substrate 510. The memory device 500 may include the first input and output pad 605 and the second input and output pad 505. A metal pattern on the upper most metal layer may be disposed in each of the external pad bonding area PA and the bit line bonding area BLBA. included in each of the cell region CELL and the peripheral circuit region PERI may be formed in a dummy pattern of the uppermost metal layer may be empty.

The memory device 500 may include a lower metal pattern 673a in the same form as the upper metal pattern 572a on the uppermost metal layer of the peripheral circuit region PERI corresponding to the upper metal pattern 572a formed on the uppermost metal layer of the cell region CELL in the external pad bonding area PA. The lower metal pattern 673a formed on the uppermost metal layer of the peripheral circuit region PERI may not contact a separate contact in the peripheral circuit region PERI. In the similar manner, an upper metal pattern having the same shape as the lower metal pattern of the peripheral circuit region PERI may be formed on the upper metal layer of the cell region CELL corresponding to the lower metal pattern formed on the uppermost metal layer of the peripheral circuit region PERI in the outer pad bonding area PA.

Lower bonding metals 671b and 672b may be formed on a second metal layer 640b of the word line bonding area WLBA. In the word line bonding area WLBA, the lower bonding metals 671b and 672b of the peripheral circuit region PERI may be electrically connected to the upper bonding metals 571b and 572b of the cell region CELL by a bonding method.

In addition, in the bit line bonding area BLBA, an upper metal pattern 592 having the same shape as the lower metal pattern 552 may be formed on the upper metal layer of the cell region CELL corresponding to the lower metal pattern 552 formed on the upper most metal layer in the peripheral circuit region PERI. A contact may not be formed on the upper metal pattern 592 formed on the uppermost metal layer in the cell region CELL.

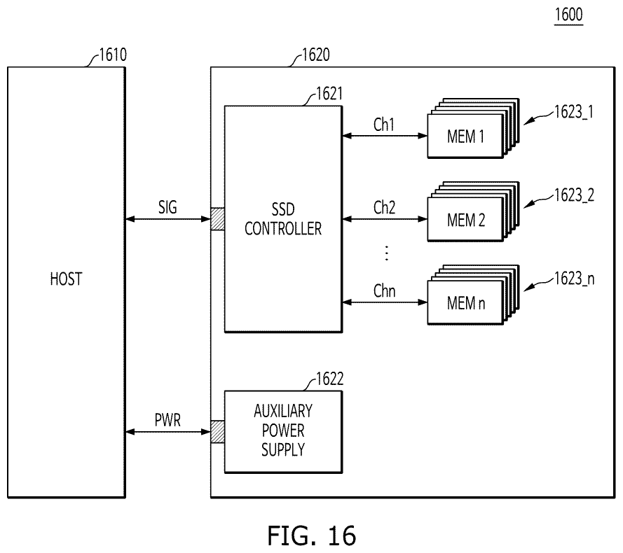

FIG. 16 is a block view illustrating an example where a memory device is applied to an SSD system 1600 according to embodiments of the present disclosure.

Referring to FIG. 16, an SSD system 1600 may include a host 1610 and an SSD 1620. The SSD 1620 may exchange a signal SIG with the host 1610 through a signal connector and may receive power PWR through a power connector. The SSD 1620 may include an SSD controller 1621, an auxiliary power supply 1622, and memory devices 1623_1, 1623_2, . . . , and 1623_n (where n is a natural number greater than or equal to two (2)). The SSD controller 1621 may transmit and receive commands, addresses, data, etc. to and from each of the memory devices 1623_1, 1623_2, . . . , and 1623_n (where n is a natural number greater than or equal to two (2)) through each of channels Ch1, Ch2, . . . , and Chn (where n is a natural number greater than or equal to two (2)).

According to embodiments, the memory devices 1623_1, 1623_2, . . . , and 1623_n may be vertically stacked NAND flash memory devices. The SSD 1620 may be implemented using the embodiments illustrated in FIGS. 1 to 15. Each of the memory devices 1623_1, 1623_2 and 1623_3 included in the SSD 1620 may include at least one memory block, and at least one memory block may have a structure illustrated in FIGS. 1 to 15 or may include a Coded GSL structure to which GSL coding is applied according to the method illustrated in FIGS. 1 to 15.

What is claimed is:

1. A memory device, comprising:
a memory cell array comprising at least one memory block comprising a plurality of cell strings, each of the plurality of cell strings being connected to one or more word lines WL arranged in one direction, and a plurality of ground selection lines GSL, wherein the plurality of cell strings comprise a first cell string and a second cell string; and
a control logic configured to control at least one of a program operation or a read operation for the memory cell array,
wherein a part of the plurality of ground select transistors GST respectively connected to the plurality of ground selection lines is programmed with a first threshold voltage, and other parts of the plurality of ground select transistors are programmed with a second threshold voltage different from the first threshold voltage,
wherein a number of memory cells configured to store user data in each of the first cell string and the second cell string, varies depending on a difference between a first location in the one direction of a ground select transistor programmed with the second threshold voltage of the first cell string, and a second location in the one direction of a ground select transistor programmed with the second threshold voltage of the second cell string.

2. The memory device as claimed in claim 1, wherein the number of memory cells, in which the user data is stored, in the first cell string is greater than the number of memory cells, in which the user data is stored, in the second cell string when a first distance between a predetermined line and the first location is smaller than a second distance between the predetermined line and the second location.

3. The memory device as claimed in claim 2, wherein a difference between the number of memory cells in the first cell string and the number of memory cells in the second cell string increases as a difference between the first distance and the second distance increases.

4. The memory device as claimed in claim 2, wherein the first location corresponds to a location of a ground select transistor farthest from the predetermined line among a plurality of ground select transistors programmed with the second threshold voltage when the first cell string includes more than one ground select transistor programmed with the second threshold voltage.

5. The memory device as claimed in claim 1, wherein the plurality of cell strings further comprises a third cell string and a fourth cell string,
wherein a first memory cell included in the third cell string and a second memory cell included in the fourth cell string are connected to the one or more word lines, and
wherein a number of bits of data stored in the first memory cell is different from a number of bits of data stored in the second memory cell based on a difference between a third location in the one direction of a ground select transistor programmed with the second threshold voltage of the third cell string, and a fourth location in the one direction of a ground select transistor programmed with the second threshold voltage in the fourth cell string.

6. The memory device as claimed in claim 5, wherein the number of bits of data stored in the first memory cell is greater than the number of bits of data stored in the second memory cell when a third distance between a predetermined line and the third location in the one direction is shorter than a fourth distance between the predetermined line and the fourth location in the one direction.

7. The memory device as claimed in claim 6, wherein a difference between the number of bits of data stored in the first memory cell and the number of bits of data stored in the second memory cell increases, as a difference between the third distance and the fourth distance increases.

8. The memory device as claimed in claim 5, wherein the number of bits of data stored in each of the first memory cell and the second memory cell is between one (1) bit and four (4) bits.

9. The memory device as claimed in claim 1, wherein the first cell string comprises a third memory cell and a fourth memory cell, and
wherein a number of bits of data stored in the third memory cell is different from a number of bits of data stored in the fourth memory cell based on a difference between a fifth location of the third memory cell in the one direction, and a sixth location of the fourth memory cell in the one direction.

10. The memory device as claimed in claim 9, wherein the number of bits of data stored in the third memory cell is smaller than the number of bits of data included in the fourth memory cell based on a fifth distance between a predetermined line and the fifth location in the one direction being shorter than a sixth distance between the predetermined line and the sixth location in the one direction.

11. The memory device as claimed in claim 1, wherein the first cell string comprises a fifth memory cell and a sixth memory cell, and
when a distance between a predetermined line and a seventh location of the fifth memory cell in the one direction is shorter than a distance between a predetermined line and an eighth location of the sixth memory cell in the one direction, the fifth memory cell is programmed to form a first threshold voltage distribution, and the sixth memory cell is programmed to form a second threshold voltage distribution having a width greater than a width of the first threshold voltage distribution.

12. The memory device as claimed in claim 1, wherein at least one dummy line is interposed between the plurality of ground selection lines and the one or more word lines, and
wherein the at least one dummy line is connected to at least one dummy cell in which the user data is not stored and at least one memory cell in which the user data is stored.

13. The memory device as claimed in claim 12, wherein the first cell string comprises a cell connected to the at least one dummy line, and
wherein the cell is a memory cell in which the user data is stored, when the first cell string comprises a ground select transistor closest to a predetermined line in the one direction among the plurality of ground select transistors programmed with the second threshold voltage.

14. The memory device as claimed in claim 1, wherein a plurality of dummy lines comprising a first dummy line and a second dummy line are interposed between the plurality of ground selection lines and the one or more word lines, and
wherein a number of memory cells in which the user data is stored and connected to the first dummy line is smaller than a number of memory cells in which the user data is stored and connected to the second dummy line when the first dummy line is closer to the plurality of ground selection lines than the second dummy line.

15. The memory device as claimed in claim 1, wherein the plurality of cell strings are grouped into N groups, and N is an integer equal to or greater than two (2),
wherein each of the plurality of cell strings comprises N ground select transistors respectively connected to N ground selection lines, and
wherein one ground select transistor, among the N ground select transistors, is programmed with the second threshold voltage, and other ground select transistors, among the N ground select transistors, are programmed with the first threshold voltage.

16. The memory device as claimed in claim 15, wherein a number of memory cells, in which the user data is stored, included in each of the cell strings in a same group, is identical.

17. The memory device as claimed in claim 1, wherein at least one ground select transistor included in a non-selected cell string among the plurality of cell strings is turned off based on a voltage between the first threshold voltage and the second threshold voltage being applied to a part of the plurality of ground selection lines, and
wherein a plurality of ground select transistors included in a selected cell string among the plurality of cell strings are turned on based on a voltage higher than the first threshold voltage and the second threshold voltage being applied to other parts of the plurality of ground selection lines.

18. A memory device, comprising:
a memory cell array comprising at least one memory block comprising a plurality of cell strings, each of the plurality of cell strings being connected to one or more word lines and a plurality of ground selection lines arranged in one direction, wherein the plurality of cell strings comprise a first cell string and a second cell string; and
a control logic configured to control at least one of a program operation or a read operation for the memory cell array,
wherein a part of a plurality of ground select transistors respectively connected to the plurality of ground selection lines is programmed with a first threshold voltage, and other parts of the plurality of ground select transistors are programmed with a second threshold voltage different from the first threshold voltage,
wherein a first memory cell included in the first cell string and a second memory cell included in the second cell string are connected to the one or more word lines, and
wherein a number of bits of data stored in the first memory cell is different from a number of bits of data stored in the second memory cell based on a difference between a first location in one direction of the ground select transistor programmed with the second threshold voltage of the first cell string, and a second location in the one direction of a ground select transistor programmed with the second threshold voltage of the second cell string.

19. The memory device as claimed in claim 18, wherein the number of bits of data stored in the first memory cell is greater than the number of bits of data stored in the second memory cell when a distance between a predetermined line and the first location in the one direction is shorter than a distance between the predetermined line and the second location in the one direction.

20. A memory device, comprising:
a memory cell array comprising a plurality of cell strings, each connected to a string selection line (SSL) and to one or more word lines (WLs) arranged in one direction;
a plurality of ground select transistors (GSTs) connected to a plurality of ground selection lines (GSLs); and
a control logic configured to perform program and read operations for the memory cell array,
wherein, for a given position on the word lines, a number of bits of data stored in memory cells connected to the same word line but included in different cell strings varies depending on a location, in the one direction, of a ground select transistor programmed with a second threshold voltage relative to a predetermined reference line.
